(19) United States
(12) Patent Application Publication
(10) Pub. No.: US 2018/0088282 A1
(43) Pub. Date: Mar. 29, 2018

(54) OPTICAL CONNECTING DEVICE, OPTICAL PROCESSING APPARATUS, METHOD FOR FABRICATING OPTICAL PROCESSING APPARATUS

(71) Applicant: SUMITOMO ELECTRIC INDUSTRIES, LTD., Osaka (JP)

(72) Inventors: Mitsuharu HIRANO, Yokohama-shi (JP); Akira Furuya, Yokohama-shi (JP)

(73) Assignee: SUMITOMO ELECTRIC INDUSTRIES, LTD., Osaka (JP)

(21) Appl. No.: 15/713,061

(22) Filed: Sep. 22, 2017

(30) Foreign Application Priority Data
Sep. 29, 2016 (JP) 2016-191409

(51) Int. Cl. G02B 6/36; H01L 31/0232; H01L 31/18

(52) U.S. Cl. CPC G02B 6/3616; H01L 31/1804; H01L 31/02325

(57) ABSTRACT

An optical connecting device includes: a holder having a first side face extending in a direction of a first axis, and first and second parts arranged arranged in a direction of a second axis intersecting the first axis; a guiding member having a side face extending in the direction of the first axis; optical fibers extending in the direction of the first axis, and a resin body disposed between the first and second parts, the first part having a first portion with a first groove extending in the direction of the second axis, and a second portion with a first opening extending from the first side face to the first groove. The resin body is disposed in the first opening and between the side face of the guiding member and the first groove and between the side face of the guiding member and the first portion of the first part.

### BACKGROUND OF THE INVENTION

### Field of the Invention

The present invention relates to an optical connecting device, an optical processing apparatus, and a method for fabricating an optical processing apparatus. This application claims the benefit of priority from Japanese Patent application No. 2016-191409 filed on Sep. 29, 2016, which is herein incorporated by reference in its entirety.

### Related Background Art

International Publication WO2002/079831 discloses an optical fiber array.

### SUMMARY OF THE INVENTION

An optical connecting device according to one aspect of the present invention includes: a holder including a first end face, a second end face, a first part, and a second part, the first end face and the second end face being arranged in a direction of a first axis, and the first part and the second part being arranged in a direction of a second axis intersecting the direction of the first axis; a guiding member supported by the first part and the second part and having a side face, the side face extending in the direction of the first axis between the first part and the second part; a plurality of optical fibers arranged along a reference plane between the first part and the second part in a direction of a third axis intersecting the direction of the second axis and the direction of the first axis; and a resin body disposed between the first part and the second part, the plurality of optical fibers extending from the first end face in the direction of the first axis, the holder having a first side face extending in the direction of the first axis, each of the first part and the second part having a first portion and a second portion, and the first portion and the second portion being arranged in the direction of the first axis, the first portion in one of the first part and the second part having a first groove extending in the direction of the second axis, the first groove having a first supporting face and a second supporting face, and the first supporting face and the second supporting face supporting the guiding member, the first portion in another of the first part and the second part having a third supporting face, the third supporting face supporting the guiding member, the second portion of the first part having a first opening extending from one of the first side face and the first end face to the first groove, in the first portions of the first part and the second part, the resin body being disposed between the side face of the guiding member and the first supporting face and the second supporting face of the first groove and between the side face of the guiding member and the third supporting face of the second part, and in the second portions of the first part and the second part, the resin body being disposed in the first opening.

An optical processing apparatus according to another aspect of the present invention includes: an optical connecting device; and a semiconductor device mounting the optical connecting device so as to be optically coupled thereto, the semiconductor device including an optical coupling element optically coupled to the optical connecting device. The optical connecting device includes: a holder including a first end face, a second end face, a first part, and a second part, the first end face and the second end face being arranged in a direction of a first axis, and the first part and the second part being arranged in a direction of a second axis intersecting the direction of the first axis; a guiding member supported by the first part and the second part and having a side face, the side face extending in the direction of the first axis between the first part and the second part; a plurality of optical fibers arranged along a reference plane between the first part and the second part in a direction of a third axis intersecting the direction of the second axis and the direction of the first axis; and a resin body disposed between the first part and the second part, the plurality of optical fibers extending from the first end face in the direction of the first axis, the holder having a first side face extending in the direction of the first axis, each of the first part and the second part having a first portion and a second portion, and the first portion and the second portion being arranged in the direction of the first axis, the first portion in one of the first part and the second part having a first groove extending in the direction of the second axis, the first groove having a first supporting face and a second supporting face, and the first supporting face and the second supporting face supporting the guiding member, the first portion in another of the first part and the second part having a third supporting face, the third supporting face supporting the guiding member, the second portion of the first part having a first opening extending from one of the first side face and the first end face to the first groove, in the first portions of the first part and the second part, the resin body being disposed between the side face of the guiding member and the first supporting face and the second supporting face of the first groove and between the side face of the guiding member and the third supporting face of the second part, and in the second portions of the first part and the second part, the resin body being disposed in the first opening.

A method for fabricating an optical processing apparatus according to still another aspect of the present invention includes steps of: preparing an optical connecting device; preparing a semiconductor device including an optical coupling element; mounting the optical connecting device on the semiconductor device to form a product such that the optical connecting device is optically coupled to the semiconductor device; and subjecting the product to heat treatment for reflowing. The optical connecting device includes: a holder including a first end face, a second end face, a first part, and a second part, the first end face and the second end face being arranged in a direction of a first axis, and the first part and the second part being arranged in a direction of a second axis intersecting the direction of the first axis; a guiding member supported by the first part and the second part and having a side face, the side face extending in the direction of the first axis between the first part and the second part; a plurality of optical fibers arranged along a reference plane between the first part and the second part in a direction of a third axis intersecting the direction of the second axis and the direction of the first axis; and a resin body disposed between the first part and the second part, the plurality of optical fibers extending from the first end face in the direction of the first axis, the holder having a first side face extending in the direction of the first axis, each of the first part and the second part having a first portion and a second portion, and the first portion and the second portion being arranged in the direction of the first axis, the first portion in one of the first part and the second part having a first groove extending in the direction of the second axis, the first groove having a first supporting face and a second supporting face, and the first supporting face and the second supporting face supporting the guiding member, the first portion in another of the first part and the second part having a third supporting face, the third supporting face supporting the guiding member, the second portion of the first part having a first opening extending from one of the first side face and the first end face to the first groove, in the first portions of the first part and the second part, the resin body being disposed between the side face of the guiding member and the first supporting face and the second supporting face of the first groove and between the side face of the guiding member and the third supporting face of the second part, and in the second portions of the first part and the second part, the resin body being disposed in the first opening.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIGS. 1A, 1B, 1C and 1D are views each showing an optical connecting device according to the present embodiment.

FIGS. 2A, 2B, 2C and 2D are views each showing an optical connecting device according to the present embodiment.

FIGS. 3A, 3B, 3C, 3D and 3E are views each showing optical connecting devices according to the present embodiment.

FIGS. 4A, 4B, 4C and 4D are views each showing an optical connecting device according to the present embodiment.

FIGS. 5A, 5B, 5C, 5D and 5E are views each showing an optical connecting device according to the present embodiment.

FIGS. 6A, 6B, 6C, 6D, 6E and 6F are views each showing an optical connecting device according to the present embodiment.

FIG. 7 is a perspective view showing a first part for the optical connecting device shown in FIGS. 1A, 1B, 1C and 1D.

FIG. 8 is a perspective view showing a first part for the optical connecting device shown in FIGS. 2A, 2B, 2C and 2D.

FIG. 9 is a perspective view showing a first part for the optical connecting device shown in FIGS. 3A, 3B, 3C, 3D and 3E.

FIG. 10 is a perspective view showing a first part for the optical connecting device shown in FIGS. 4A, 4B, 4C and 4D.

FIG. 11 is a perspective view showing a first part for the optical connecting device shown in FIGS. 5A, 5B, 5C, 5D and 5E.

FIG. 12 is a perspective view showing a first part for the optical connecting device shown in FIGS. 6A, 6B, 6C, 6D, 6E and 6F.

FIGS. 13A, 13B, 13C and 13D are schematic views showing major steps in the method for fabricating the optical connecting device according to the present embodiment.

FIGS. 14A, 14B, 14C, 14D and 14E are schematic views showing major steps in the method for fabricating the optical connecting device according to the present embodiment.

FIGS. 15A, 15B, 15C and 15D are schematic views showing major steps in the method for fabricating an optical processing apparatus.

FIGS. 16A and 16B are views each showing an exemplary silicon photonics semiconductor device applicable to the optical apparatus according to the present embodiment.

FIG. 17 is a schematic view showing the optical processing apparatus according to the present embodiment.

FIG. 18 is a schematic view showing the optical processing apparatus according to the present embodiment.

### DESCRIPTION OF THE EMBODIMENTS

The optical fiber array disclosed in International Publication WO2002/079831 includes a substrate having V-shaped grooves and U-shaped grooves, guide pins disposed in the U-shaped grooves, an array of optical fibers disposed in the V-shaped grooves, and a lid for pressing the guide pin and the optical fiber. The guide pins and the optical fibers make contact with the support face of the lid.

An optical connecting device including an array of optical fibers is optically connected to another optical component. The other optical component can be an optical connector, and may be an active device, such as a semiconductor device. Providing the optical connecting device with an improved heat tolerance can extend the application thereof. The optical connecting device includes several components made of different materials. These materials have respective thermal expansion coefficients, and the components of different materials are thermally deformed according to their respective thermal expansion coefficients. Studies conducted by the inventors reveal that one way to improve the heat tolerance of the optical connecting device is to reduce stress caused by the difference in thermal deformations thereof.

It is an object of one aspect of the present invention to provide an optical connecting device with a desired heat tolerance. It is another object of another aspect of the present invention to provide an optical processing apparatus including the optical connecting device. It is an object of still another aspect of the present invention to provide a method for fabricating an optical processing apparatus including the optical connecting device.

Specific embodiments according to the above aspects will be described below.

An optical connecting device according to an embodiment includes: (a) a holder including a first end face, a second end face, a first part, and a second part, the first end face and the second end face being arranged in a direction of a first axis, and the first part and the second part being arranged in a direction of a second axis intersecting the direction of the first axis; (b) a guiding member supported by the first part and the second part and having a side face, the side face extending in the direction of the first axis between the first part and the second part; (c) a plurality of optical fibers arranged along a reference plane between the first part and the second part in a direction of a third axis intersecting the direction of the second axis and the direction of the first axis; and (d) a resin body disposed between the first part and the second part, the plurality of optical fibers extending from the first end face in the direction of the first axis, the holder having a first side face extending in the direction of the first axis, each of the first part and the second part having a first portion and a second portion, and the first portion and the second portion being arranged in the direction of the first axis, the first portion in one of the first part and the second part having a first groove extending in the direction of the second axis, the first groove having a first supporting face and a second supporting face, and the first supporting face and the second supporting face supporting the guiding member, the first portion in another of the first part and the second part having a third supporting face, the third supporting face supporting the guiding member, the second portion of the first part having a first opening extending from one of the first side face and the first end face to the first groove, in the first portions of the first part and the second part, the resin body being disposed between the side face of the guiding member and the first supporting face and the second supporting face of the first groove and between the side face of the guiding member and the third supporting face of the second part, and in the second portions of the first part and the second part, the resin body being disposed in the first opening.

The optical connecting device allows the first portions of the first and second parts to hold the guide member therebetween with the resin body, which is disposed between the side face of the guide member and the first and second supporting faces of the first groove and between the side face of the guide member and the supporting face of the second part, and is also disposed between the second portions of the first part and the second part. The guide member held by the holder is deformed by temperature change in the optical connecting device. The first opening, which is located in the first side face or the first end face of the holder, does not extend in the direction of the second axis in which the first and second parts of the holder are arranged, but is deepened inward to communicate with the first groove in the holder. The resin body is also disposed in the first opening between the first part and the second part, and extends from the first side face or the first end face of the holder to the first groove through the first opening, which communicates with the first groove. The resin body in the second portion, specifically in the first opening with few restrictions imposed by the holder, can be deformed more easily than that in the first portion of the holder. This ease of deformation is effective in reducing the stress of the resin body.

In the optical connecting device according an embodiment, the first end face is in the first portions of the first part and the second part, the resin body is in contact with the side face of the guiding member in the second portions of the first part and the second part, and the first opening extends from the first side face of the holder in the direction of the third axis.

In the optical connecting device, the first opening is deepened from the first side face in the direction of the third axis, so that the resin body continues from the first opening to the first groove. The continuous resin makes it possible to reduce the stress of the resin body.

In the optical connecting device according to an embodiment, the second portion of the first part has a groove extending from the first side face to the first groove, and the groove has a depth shallower than that of the first groove.

In the optical connecting device, providing the first opening with the groove of a depth smaller than the first groove hardly reduces the mechanical strength of the holder.

In the optical connecting device according to an embodiment, the second portion of the first part has a groove extending from the first side face to the first groove, and the groove has a depth larger than that of the first groove.

In the optical connecting device, providing the first opening with the groove of a depth larger than the first groove makes it easy for resin in the first groove to flow to the groove, working as the first opening before curing.

In the optical connecting device according to an embodiment, the second portions of the first part and the second part are apart from the end face and the second end face, the holder has a second side face opposite to the first side face, the second portion of the first part has a second opening and a third opening, the second opening is disposed in the second side face, and the third opening connects the second opening to the first groove, the second opening extends in a direction of the second side face to the first side face, the resin body is in contact with the side face of the guiding member in the second portions of the first part and the second part, and is disposed in the first opening, and the resin body extends from the first groove in the second opening and the third opening in the second portions of the first part and the second part.

In the optical connecting device, the resin body in each first groove communicates with the resin body in not only the first opening but also the second and third openings.

In the optical connecting device according to an embodiment, the first opening, the second opening and the third opening are aligned in a line.

In the optical connecting device, the resin body in the first groove is continuous with that in the first opening, the second opening, and the third opening, which are linearly aligned. The alignment of these openings makes it easy for the resin in the openings to deform in the direction of the alignment.

In the optical connecting device according to an embodiment, the second portions of the first part and the second part are apart from the first end face and the second end face, and the first opening is apart from the plurality of optical fibers.

In the optical connecting device, the first opening does not interfere with the arrangement of the optical fibers.

In the optical connecting device according to an embodiment, the first end face is in the first portions of the first part and the second part, the first opening is in the first end face, and the guiding member protrudes from the first groove and extends in the first opening.

In the optical connecting device, the resin body in the first groove is continuous with the resin portion in the first opening, which can more easily deform as compared with the resin body in the first groove.

In the optical connecting device according to an embodiment, the guiding member includes a guide pin made of metal.

In the optical connecting device, the guide member can include a guide pin.

In the optical connecting device according to an embodiment, the guiding member includes a guide pipe made of metal.

In the optical connecting device, the guide member can include a guide pipe.

An optical processing apparatus according to an embodiment includes: (a) an optical connecting device; and (b) a semiconductor device mounting the optical connecting device so as to be optically coupled thereto, the semiconductor device including an optical coupling element optically coupled to the optical connecting device. The optical connecting device includes: a holder including a first end face, a second end face, a first part, and a second part, the first end face and the second end face being arranged in a direction of a first axis, and the first part and the second part being arranged in a direction of a second axis intersecting the direction of the first axis; a guiding member supported by the first part and the second part and having a side face, the side face extending in the direction of the first axis between the first part and the second part; a plurality of optical fibers arranged along a reference plane between the first part and the second part in a direction of a third axis intersecting the direction of the second axis and the direction of the first axis; and a resin body disposed between the first part and the second part, the plurality of optical fibers extending from the first end face in the direction of the first axis, the holder having a first side face extending in the direction of the first axis, each of the first part and the second part having a first portion and a second portion, and the first portion and the second portion being arranged in the direction of the first axis, the first portion in one of the first part and the second part having a first groove extending in the direction of the second axis, the first groove having a first supporting face and a second supporting face, and the first supporting face and the second supporting face supporting the guiding member, the first portion in another of the first part and the second part having a third supporting face, the third supporting face supporting the guiding member, the second portion of the first part having a first opening extending from one of the first side face and the first end face to the first groove, in the first portions of the first part and the second part, the resin body being disposed between the side face of the guiding member and the first supporting face and the second supporting face of the first groove and between the side face of the guiding member and the third supporting face of the second part, and in the second portions of the first part and the second part, the resin body being disposed in the first opening.

The optical processing apparatus can include a device formed by a fabricating process requiring a reflow step.

A method for fabricating an optical processing apparatus according to an embodiment includes steps of: (a) preparing an optical connecting device; (b) preparing a semiconductor device including an optical coupling element; (c) mounting the optical connecting device on the semiconductor device to form a product such that the optical connecting device is optically coupled to the semiconductor device; and (d) subjecting the product to heat treatment for reflowing. The optical connecting device includes: a holder including a first end face, a second end face, a first part, and a second part, the first end face and the second end face being arranged in a direction of a first axis, and the first part and the second part being arranged in a direction of a second axis intersecting the direction of the first axis; a guiding member supported by the first part and the second part and having a side face, the side face extending in the direction of the first axis between the first part and the second part; a plurality of optical fibers arranged along a reference plane between the first part and the second part in a direction of a third axis intersecting the direction of the second axis and the direction of the first axis; and a resin body disposed between the first part and the second part, the plurality of optical fibers extending from the first end face in the direction of the first axis, the holder having a first side face extending in the direction of the first axis, each of the first part and the second part having a first portion and a second portion, and the first portion and the second portion being arranged in the direction of the first axis, the first portion in one of the first part and the second part having a first groove extending in the direction of the second axis, the first groove having a first supporting face and a second supporting face, and the first supporting face and the second supporting face supporting the guiding member, the first portion in another of the first part and the second part having a third supporting face, the third supporting face supporting the guiding member, the second portion of the first part having a first opening extending from one of the first side face and the first end face to the first groove, in the first portions of the first part and the second part, the resin body being disposed between the side face of the guiding member and the first supporting face and the second supporting face of the first groove and between the side face of the guiding member and the third supporting face of the second part, and in the second portions of the first part and the second part, the resin body being disposed in the first opening.

The method of fabricating the optical processing apparatus can reduce the possibility of breakage of the optical connecting device occurring in and after the reflow process.

Teachings of the present invention can be readily understood by considering the following detailed description with reference to the accompanying drawings shown as examples. Referring to the accompanying drawings, embodiments of an optical connecting device, an optical processing apparatus, a method for fabricating an optical connecting device, and a method for fabricating an optical processing apparatus according to the present invention will be described. To facilitate understanding, identical reference numerals are used, where possible, to designate identical elements that are common to the figures.

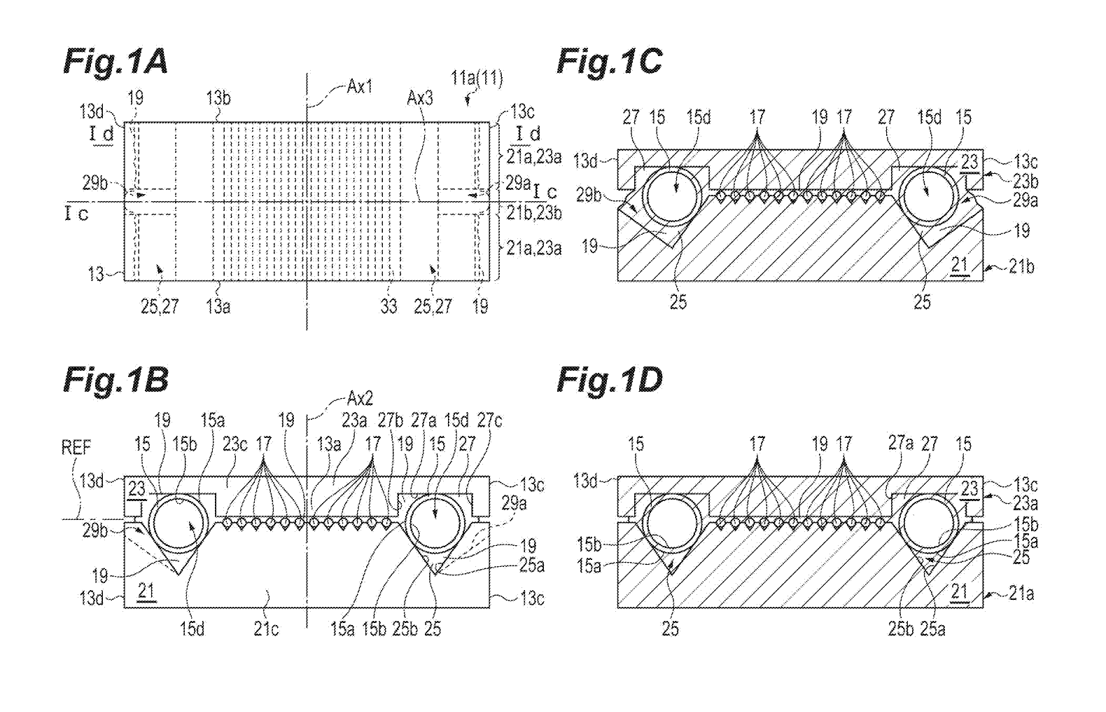

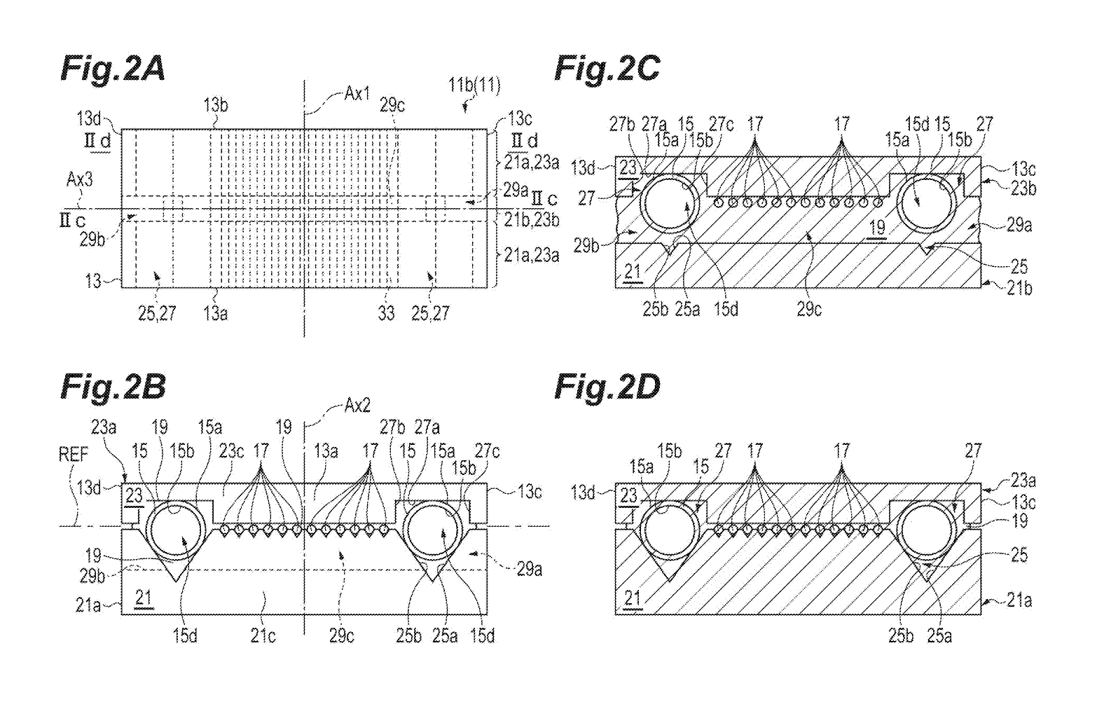

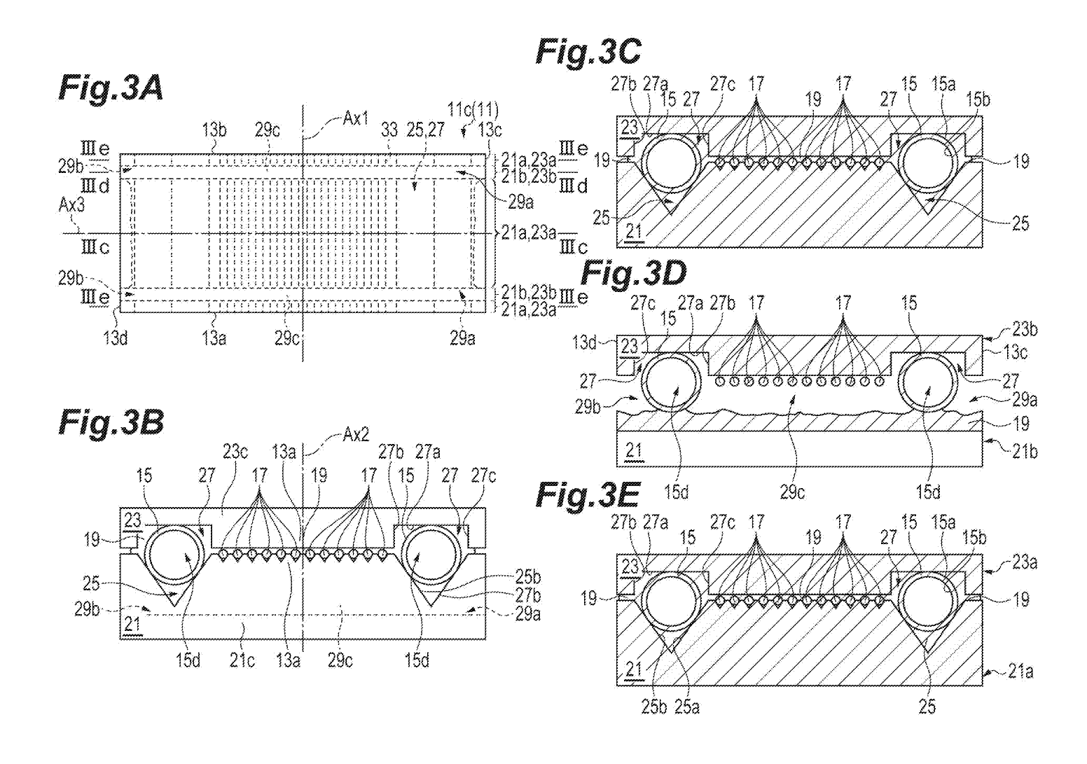

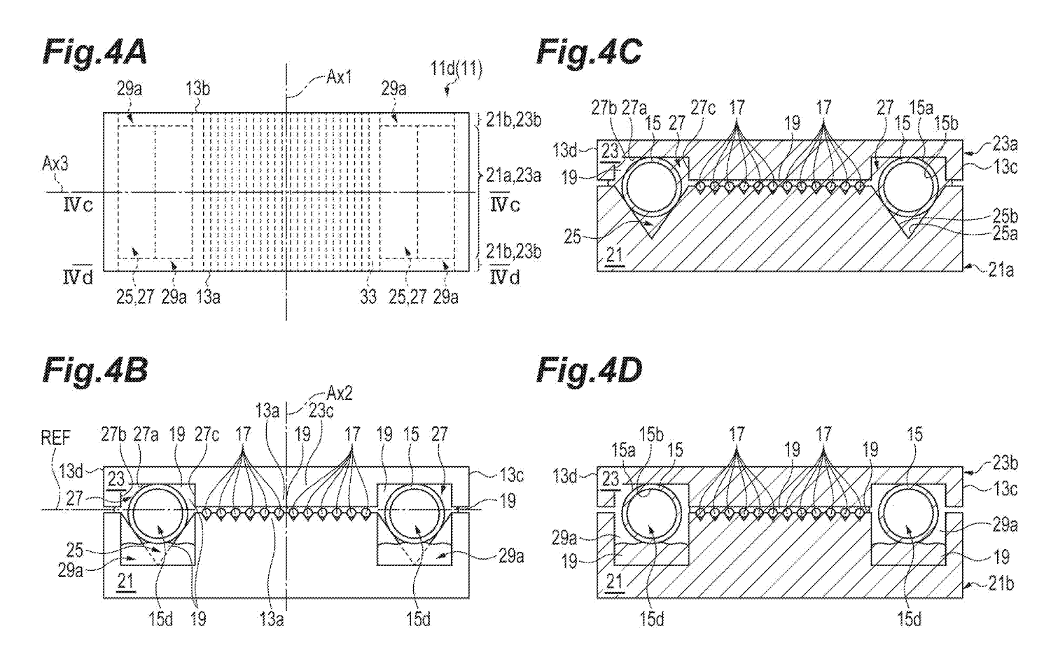

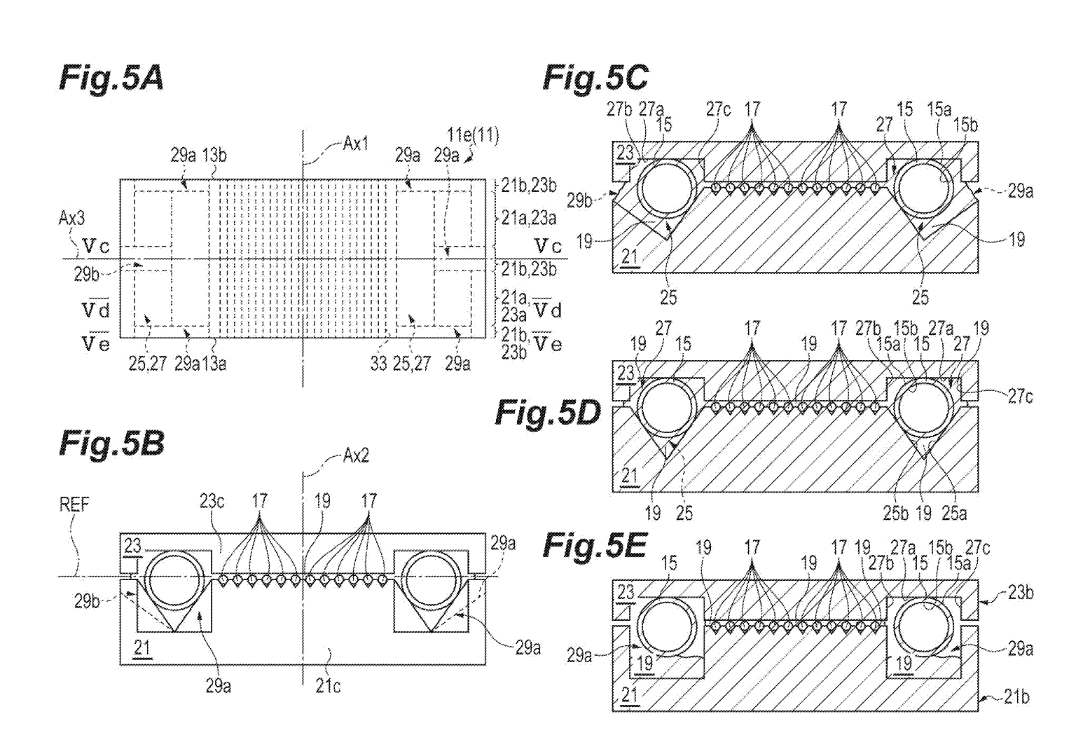

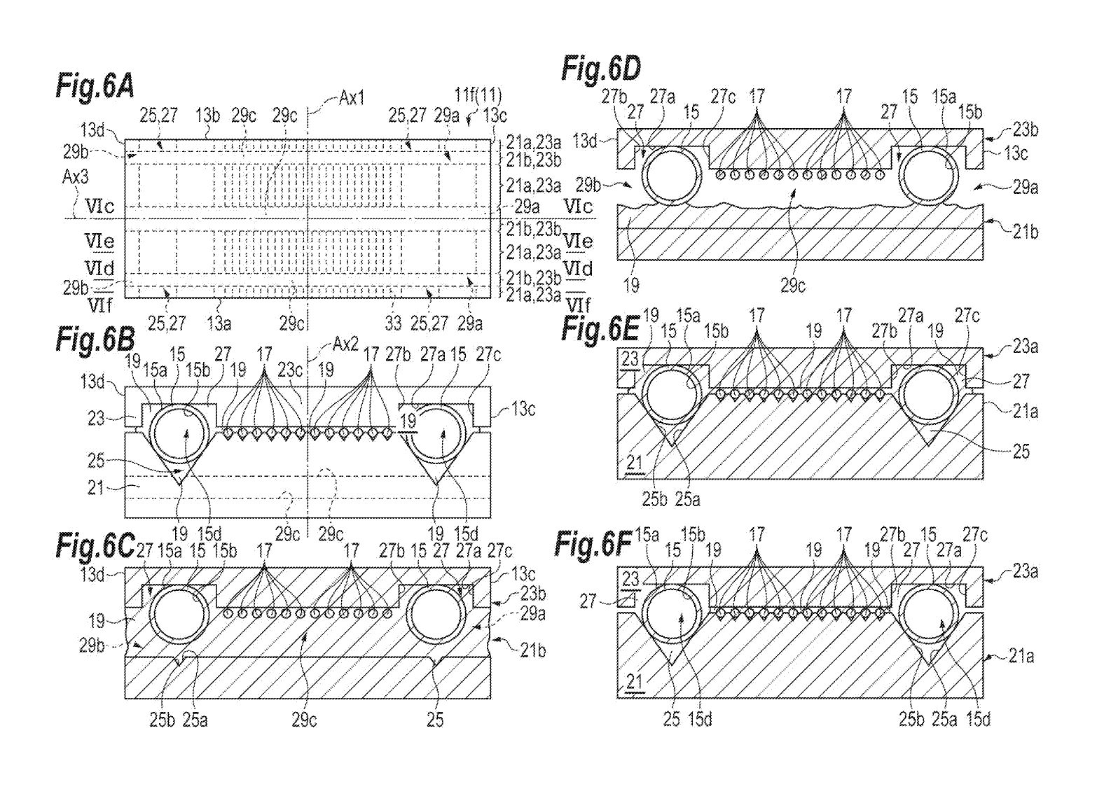

With reference to FIGS. 1A, 1B, 1C and 1D, FIGS. 2A, 2B, 2C and 2D, FIGS. 3A, 3B, 3C, 3D and 3E, FIGS. 4A, 4B, 4C and 4D, FIGS. 5A, 5B, 5C, 5D and 5E, FIGS. 6A, 6B, 6C, 6D, 6E and 6F, an optical connecting device according to the present embodiment will be described below. FIG. 1A is a plan view showing an optical connecting device 11a according to the present embodiment. FIG. 1B is a front view showing the optical connecting device 11a shown in FIG. 1A. FIG. 1C is a cross sectional view taken along the line Ic-Ic shown in FIG. 1A. FIG. 1D is a cross sectional view taken along the line Id-Id shown in FIG. 1A. FIG. 2A is a plan view showing an optical connecting device 11b according to the present embodiment. FIG. 2B is a front view showing the optical connecting device 11b shown in FIG. 2A. FIG. 2C is a cross sectional view taken along the line IIc-IIc shown in FIG. 2A. FIG. 2D is a cross sectional view taken along the line IId-IId shown in FIG. 2A. FIG. 3A is a plan view showing an optical connecting device 11c according to the present embodiment. FIG. 3B is a front view showing the optical connecting device 11c shown in FIG. 3A. FIG. 3C is a cross sectional view taken along line IIIc-IIIc shown in FIG. 3A. FIG. 3D is a cross sectional view taken along the line IIId-IIId shown in FIG. 3A. FIG. 3E is a cross sectional view taken along line IIIe-IIIe shown in FIG. 3A. FIG. 4A is a plan view showing an optical connecting device 11d according to the present embodiment. FIG. 4B is a front view showing the optical connecting device 11d shown in FIG. 4A. FIG. 4C is a cross sectional view taken along the line IVc-IVc shown in FIG. 4A. FIG. 4D is a cross sectional view taken along the line IVd-IVd shown in FIG. 4A. FIG. 5A is a plan view showing an optical connecting device 11e according to the present embodiment. FIG. 5B is a front view showing the optical connecting device 11e shown in FIG. 5A. FIG. 5C is a cross sectional view taken along the line Vc-Vc shown in FIG. 5A. FIG. 5D is a cross sectional view taken along the line Vd-Vd shown in FIG. 5A. FIG. 5E is a cross sectional view taken along line Ve-Ve shown in FIG. 5A. FIG. 6A is a plan view showing an optical connecting device 11f according to the present embodiment. FIG. 6B is a front view showing the optical connecting device 11f shown in FIG. 6A. FIG. 6C is a cross sectional view taken along the line VIc-VIc shown in FIG. 6A. FIG. 6D is cross sectional view taken along the line VId-VId shown in FIG. 6A. FIG. 6E is a cross sectional view taken along the line VIe-VIe shown in FIG. 6A. FIG. 6F is a cross sectional view taken along the line VIf-VIf shown in FIG. 6A.

The optical connecting device 11 (11a, 11b, 11c, 11d, 11e, and 11f) includes a holder 13, a guide member 15, a plurality of optical fibers 17, and a resin body 19. The holder 13 includes a first end face 13a and a second end face 13b, which are arranged in the direction of the first axis Ax1, and a first side face 13c extending in the direction of a first axis Ax1. Further, the holder 13 includes a first part 21 and a second part 23, which are arranged in the direction of a second axis Ax2 intersecting that of the first axis Ax1. The first and second parts 21 and 23 are made of, for example, glass, which can include, for example, quartz, Tempax, Pyrex (registered trademark). The material of the resin body 19 may include, for example, a silicone-based, epoxy-based or acrylic-based resin.

The guide member 15 is supported by the first part 21 and the second part 23. The guide member 15 has an outer side face 15a, which extends from one of the guide member 15 end to the other end. The guide member 15 is disposed between the first and second parts 21 and 23 and extends in the direction of the first axis Ax1. The guide member 15 may include, for example, a guide pin. The guide pin can be made of, for example, metal, and the metal guide pin includes, for example, copper, nickel, iron, cobalt, tungsten or an alloy containing one or more of these metals. The guide pin working as the guide member 15 has the outer side face 15a. The outer side face 15a extends in the direction of the first axis Ax1 between the first and second parts 21 and 23. Alternatively, the guide member 15 may include a guide pipe. The guide pipe can be made of, for example, metal, and the metal guide pipe includes, for example, copper, nickel, iron, cobalt, tungsten or an alloy containing one or more of these metals. The guide pipe working as the guide member 15 has an inner face 15b in addition to the outer face 15a, and the outer and inner faces 15a and 15b extend in the direction of the first axis Ax1 between the first and second parts 21 and 23. Specifically, the inner side face 15b extends from one end of the guide member 15 to the other end in the direction of the first axis Ax1 to define a through-hole 15d.

The optical fibers 17, which are disposed between the first and second parts 21 and 23, are arranged along the reference plane REF in the direction of a third axis Ax3, the direction of which intersects the directions of the first and second axes Ax1 and Ax2. Each of the optical fibers 17 extends from the first end face 13a in the direction of the first axis Ax1. The resin body 19 is disposed between the first and the second parts 21 and 23, which support the optical fibers 17.

The first part 21 has a first portion 21a and a second portion 21b, which are arranged in the direction of the first axis Ax1, and the second part 23 has a first portion 23a and a second portion 23b, which are arranged in the direction of the first axis Ax1. The first portion (21a or 23a) of either one of the first part 21 and the second part 23, for example, the first portion 21a of the first part 21 in the present embodiment, has a channel or groove 25 extending in the direction of the first axis Ax1. The first groove 25 has a first supporting face 25a and a second supporting face 25b, which support the guide member 15. The first portion (23a or 21a) of the other of the first part 21 and the second part 23, specifically, the first portion 23a of the second part 23 in the present embodiment has a third supporting face 25c supporting the guide member 15. If needed, the second part 23 may have a second groove 27, which provides the third supporting face 25c. The second groove 27 has a fourth side face 27b and a fifth side face 27c. The first supporting face 25a, the second supporting face 25b, and the third supporting face 27a extend in the direction of the first axis Ax1. The second portion 21b of the first part 21 has a first opening 29a, and the first opening 29a communicates with the first groove 25 and is provided in the first side face 13c or the first end face 13a of the holder 13.

In the first portions 21a and 23a, the resin body 19 is disposed between the side face of the guide member 15 (the outer face 15a) and the first and second supporting faces 25a and 25b of the first groove 25 and between the third supporting face 27a of the second part 23 and the side face (the outer face 15a) of the guide member 15. In the second portions 21b and 23b, the resin body 19 is provided in the first opening 29a.

The optical connecting device 11 (11a, 11b, 11c, 11d, 11e, and 11f) allows the first portion 21a of the first part 21 and the first portion 23a of the second part 23 to hold the guide member 15 therebetween by use of the resin body 19, which is disposed between the outer side face 15a of the guide member 15 and the first and second supporting faces 25a and 25b of the first groove 25 and between the outer face 15a of the guide member 15 and the supporting face 27a of the second part 23, and the resin body 19 is also disposed between the second portion 21a of the first part 21 and the second portion 23b of the second part 23. The guide member 15 held by the holder 13 is deformed by temperature changes in the optical connecting device 11. The first opening 29a, which is located in the first end face 13a or the first side face 13c of the holder 13, does not extend in the direction of the second axis Ax2 in which the first part 21 and the second part 23 are arranged, and is deepened inward to communicate with the first groove 25 in the holder 13. The resin body 19 is also disposed in the first opening 29a of the holder 13 between the first and second parts 21 and 23, and extends in the first opening 29a, which communicates with the first groove 25, from the first side face 13c or the first end face 13a of the holder 13 to the first groove 25. The holder with the first opening 29a, which extends inward from the first side face 13c or the first end face 13a, places less restriction in deformation on the resin body 19 in the second portions (21b and 23b), specifically in the first opening 29a, so that the resin in the first opening 29a can be deformed more easily than that in the first portion of the holder 13. This ease of deformation is effective in reducing the stress of the resin body 19.

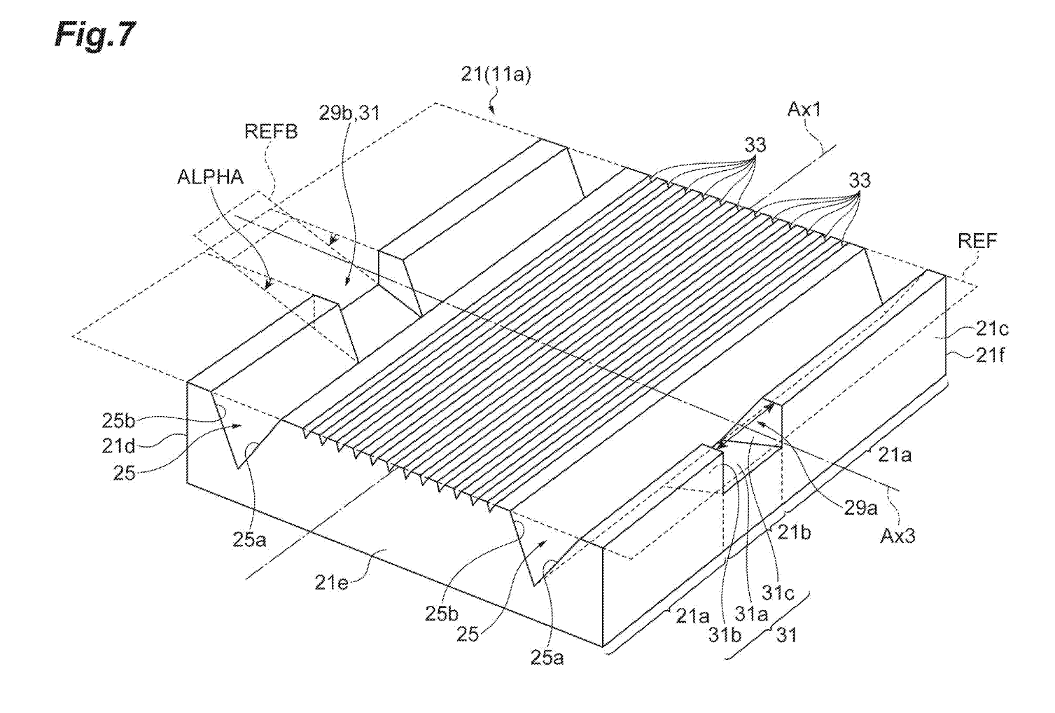

With reference to FIG. 7 in addition to FIGS. 1A, 1B, 1C and 1D, the optical connecting device 11a will be described below. Referring to FIG. 1A, the first groove 25 in the first part 21, the second groove 27 in the second part 23 and the support groove 33 for the optical fiber are drawn by broken lines. FIG. 7 is a perspective view showing the first part 21 for the optical connecting device 11a shown in FIG. 1A.

As shown in FIGS. 1A to 1D, the first opening 29a is deepened inward to extend from the first side face 13c of the holder 13 in the direction of the third axis Ax3, and the second opening 29b is deepened inward to extend from the side face 13d of the holder 13 in the direction of the third axis Ax3. The second side face 21d is opposite to the first side face 21c. Referring to FIG. 7, the optical connecting device 11a is shown. The first and second openings 29a and 29b have respective grooves 31, which extends from the first side face 21c and the second side face 21d, in the second portion 21b. These grooves 31 extend in a direction from one of the first and second side faces 21c and 21d to the other. In the present embodiment, each groove 31 has a bottom face 31a, a first side face 31b and a second side face 31c. The first opening 29a, the second opening 29b, and the groove 31 are disposed away from the optical fibers 17 and the support grooves 33, so that the first opening 29a, the second opening 29b and the grooves 31 do not interfere with the arrangement of the optical fibers 17. The first opening 29a, the second opening 29b, and the grooves 31 each have a length short enough not to reach the supporting grooves 33. The first and second openings 29a and 29b of the optical connecting device 11a are connected to the respective first grooves 25, and these connections hardly lower the mechanical strength of the first part 21. The support grooves 33 extend from the first end face 21e to the second end face 21f in the thick region (located between the first grooves 25) of the first part 21.

In the present embodiment, the first part 21 includes a first portion 21a, a second portion 21b and another first portion 21a, which are arranged in the direction of the axis Ax1. The first portion 21a and the other first portion 21a include a first end face 21e and a second end face 21f, respectively. The grooves 31 are separated from the first end face 21e and the second end face 21f, which are included by the first portion 21a and the other first portion 21a of the first part 21 (the first portion 23a of the second part 23), respectively. Furthermore, the second portion 21b of the first part 21 and the second portion 23b of the second part 23 are separated from the first end face 13a and the second end face 13b. Each groove 31 has a bottom face 31a extending along the reference plane REFB, and the reference plane REF forms an angle ALPHA with respect to the reference plane REFB. The angle ALPHA is preferably in the range of, for example, 0 to 70 degrees measured in a clockwise direction defined as the positive direction. In the present embodiment, the groove 31 on the first side face 21c of the first part 21 is aligned with the groove 31 on the second side face 21d. If needed, these grooves 31 on the first and second sides 21c and 21d may not be aligned with each other in the first part 21.

In fabricating the optical connecting device 11a, optical fibers (if needed, a guide member) are arranged between the members for the first and second parts 21 and 23, and resin is applied to an array of the optical fibers on one of the members. The resin thus applied is cured to fix the optical fibers with the members. In order to fill the gap between the outer face 15a of the guide member 15 and the supporting faces (25a, 25b, 27a, 27b, and 27c) of the first and second grooves 25 and 27 with the resin body 19 (or an additional resin), resin for the resin body 19 can be supplied from the first opening 29a and the second opening 29b, and an excess resin of the resin thus supplied flows out of the end portions (the end portion(s) on the first and second end faces 13a and/or 13b) of the first and second grooves 25 and 27.

In the optical connecting device 11a thus fabricated, the holder 13 and the guide member 15 deform in response to temperature changes thereof. The deformation of the guide member 15 is transmitted to the resin body 19. In the holder 13, the resin body 19 is provided in the first and second openings 29a and 29b, which extend in one direction from the first groove 25 to the first side face 13c (the first side face 21c of the part 21) and another direction from the first groove 25 to the second side face 13d (the second side face 21d of the first part 21) in the present embodiment, respectively, specifically, along the direction of the third axis Ax3. These directions are different from the direction (the second axis Ax2) of the arrangement of the first and second parts 21 and 23 bonded to each other. The first and second openings 29a and 29b thus arranged allow the resin body 19 to deform along the first and second openings 29a and 29b.

The resin body 19 is disposed in the first portions 21a and 23a between the first part 21 and the second part 23, and is in direct contact with the outer face 15a of the guide member 15 in the first and second grooves 25 and 27. The resin body 19 in the second portions 21b and 23b can deform in the first and second opening 29a and 29b free from the holder 13 in the direction in which the reference plane REF extends. This deformation is useful for reducing the internal stress of the resin body 19.

In the optical connecting device 11a, the first opening 29a (the second opening 29b), which extends from the first groove 25 in the direction of the third axis Ax3 to reach the first side face 13c, makes it possible to reduce stress in the resin body 19 continuous from the first groove 25 to the first opening 29a (the second opening 29b). The first opening 29a (the second opening 29b) can provide the optical connecting device 11a with a desired heat tolerance.

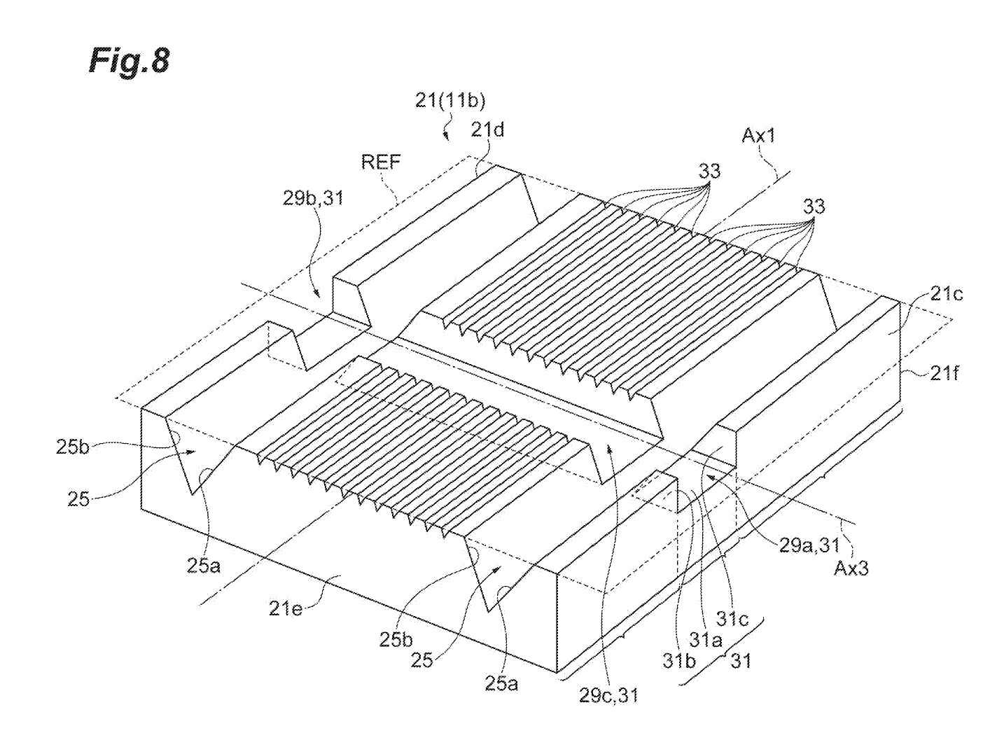

With reference to FIGS. 2A, 2B, 2C and 2D and FIG. 8, the optical connecting device 11b will be described below. Referring to FIG. 2A, the supporting grooves 33 for the optical fibers 17 and the first and second grooves 25 and 27 of the first and second parts 21 and 23 are drawn by broken lines. FIG. 8 is a perspective view showing the first part 21 for the optical connecting device 11b shown in FIG. 2A. The second portions 21b and 23b are separated apart from the first end face 13a (the first end face 21e) and the second end face 13b (the second end face 21f) of the holder 13. In the present embodiment, the first part 21 includes a first portion 21a, a second portion 21b and another first portion 21a, which are arranged in the direction of the axis Ax1. The first portion 21a and the other first portion 21a include the first end face 21e and the second end face 21f, respectively.

As shown in FIGS. 2A, 2B, 2C and 2D, the first opening 29a, the second opening 29b and the third opening 29c are disposed in the second portion 21b. The first opening 29a extends from the first side face 13c of the holder 13 in the direction of the third axis Ax3; the second opening 29b extends from the second side face 13d of the holder 13 in the direction of the third axis Ax3; and the third opening 29c connects the first opening 29a and the second opening 29b to each other. The second side face 21d is opposite to the first side face 21c. In the present embodiment, the first opening 29a, the second opening 29b, and the third opening 29c are aligned in a line. The resin body 19 is continuous from the first groove 25 and the second groove 27 to the first opening 29a, and the second opening 29b, and the third opening 29c, which is connected to the first groove 25 and the second groove 27. The first opening 29a, the second opening 29b and the third opening 29c thus aligned allows deformation of the resin body 19 in the direction of the alignment. Referring to FIG. 8, in the optical connecting device 11b, the first and second openings 29a and 29b thus arranged have respective grooves 31, which extend from the first and second side faces 21c and 21d of the first part 21 to the first grooves 25. The third opening 29c also has a groove 31 that connects one of the first grooves 25, which is closer to the first side face 21c in the second portion 21b, to the other of the first grooves 25, which is closer to the second side face 21d. These grooves 31 extend in a direction from one of the first and second side faces 21c and 21d to the other. In the present embodiment, each groove 31 has a bottom face 31a, a first side face 31b and a second side face 31c. The grooves 31 of the first opening 29a and the second opening 29b are separated from the optical fibers 17 and the supporting grooves 33, and the groove 31 of the third opening 29c runs across the supporting grooves 33.

The resin body 19 is in direct contact with the outer face 15a of the guide member 15 in the second portions 21b and 23b of the first and second parts 21 and 23, and is provided continuously in the first opening 29a, the second opening 29b, and the third opening 29c. The resin body 19 extends from the first grooves 25 into the third opening 29c in the second portion 21b of the first part 21 and the second portion 23b of the second part 23, and the third opening 29c can connect the resin body 19 in the first opening 29a and one of the first grooves 25 with the resin body 19 in the second opening 29b and the other of the first grooves 25, so that the resin body 19 forms a single resin as a whole. The resin body 19 is continuous not only to the first opening 29a and the one of the first grooves 25 but also the second opening 29b and the other of the first grooves 25 via the third opening 29c. In the present embodiment, the grooves 31 have a depth smaller than that of each first groove 25. The addition of the grooves 31 shallower than the first grooves 25 to the holder 13 hardly reduces the mechanical strength of the holder 13. The grooves 31 are fabricated using, for example, a precision grinding machine.

In fabricating the optical connecting device 11b, the optical fibers 17 (if needed, the guide member 15) are arranged between members for the first and second parts 21 and 23, and these members thus arranged hold the optical fibers 17 with resin for bonding, which is applied to the optical fibers 17 and the members and cured, to provide the holder 13. In order to fill gaps between the outer face 15a of the guide member 15 and the faces (25a, 25b, 27a, 27b, and 27c) of the first grooves 25 and the second grooves 27 with the resin body 19, resin (or additional resin) can be supplied thereto through the first and second openings 29a and 29b and, if any, surplus resin of the resin thus supplied flows out from the ends of the first grooves 25 and the second grooves 27 (ends located at the first end face 13a and the second end face 13b). In fabricating the optical connecting device 11b, the third opening 29c is useful to introduce resins (or additional resins), which are supplied from the first opening 29a and the second opening 29b, into the first opening 29a, the second opening 29b and the two grooves 31.

In the optical connecting device 11b thus fabricated, the holder 13 and the guide member 15 deform according to the temperature changes of the optical connecting device 11b. The deformation of the guide member 15 causes that of the resin body 19, which extends to the first opening 29a, the second opening 29b, and the third opening 29c of the holder 13. The first opening 29a extends in a direction (for example, in the direction of the third axis Ax3) from one of the first grooves 25 to the first side face 13c (the first side face 21c of the first part 21), and the second opening 29b extends in the direction from the other first groove 25 to the second side face 13d (the second side face 21d of the first part 21), and the first and second openings 29a and 29b are connected via the respective first grooves 25 to the third opening 29c. The above directions are different from the arrangement direction (the second axis Ax2) in which the first and second parts 21 and 23 bonded are arranged. The resin body 19 has portions in the first and second openings 29a and 29b, which deform along the first and second openings 29a and 29b, respectively.

The resin body 19 provided between the first part 21 and the second part 23 is in contact with the outer side face 15a of the guide member 15 in the first and second grooves 25 and 27, and holds the guide member 15 in the first portion 21a of the first part 21 and the first portion 23a of the second part 23. The resin body 19 in the second portions 21b and 23b is deformed in the first and second openings 29a and 29b with less restriction provided by the holder 13 in the direction in which the reference plane REF extends. This deformation is effective in reducing the internal stress of the resin body 19.

The optical connecting device 11b, having the first and second openings 29a and 29b that extend in the direction of the third axis Ax3 to reach the first and second side faces 13c and 13d, respectively, allows the resin body 19 to continue from the first and second openings 29a and 29b to the respective first grooves 25, thereby making it possible to reduce the internal stress therein. The third opening 29c connects the two first grooves 25 to each other, so that the resin body 19 in the third opening 29c is effective in reducing, if any, imbalance in stress in the resin body 19 between the first opening 29a and the second opening 29b. Such optical connecting device 11b has a desired heat tolerance.

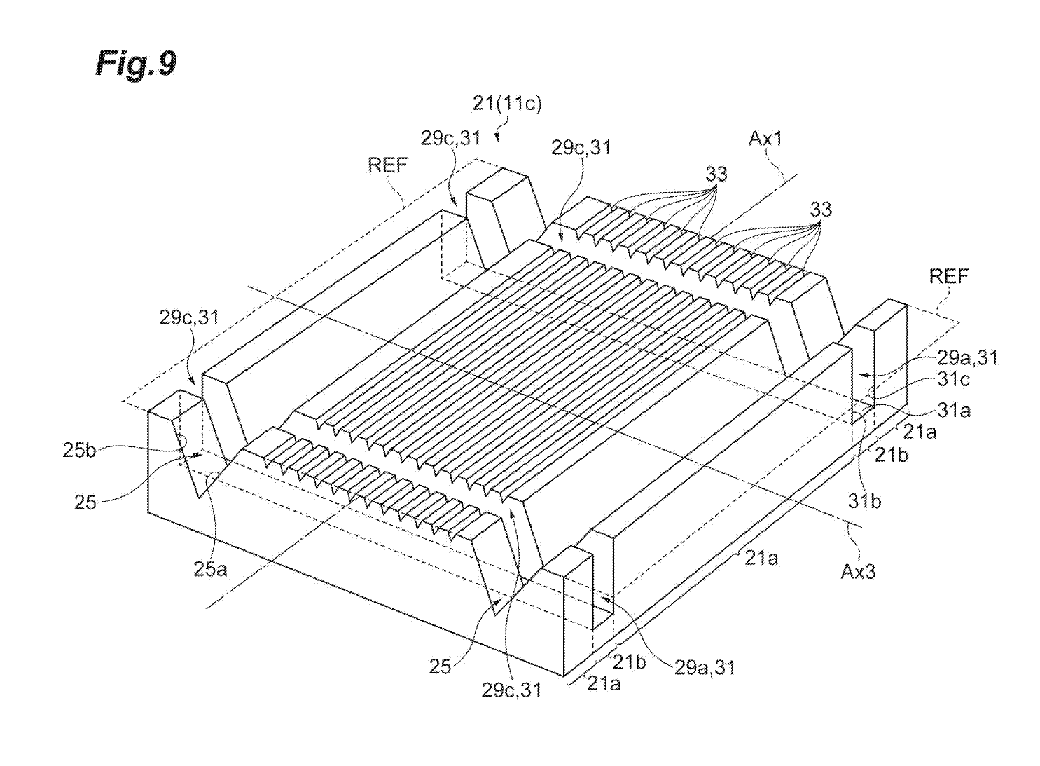

With reference to FIGS. 3A, 3B, 3C, 3D and 3E and FIG. 9, the optical connecting device 11c will be described below. In FIG. 3A, the first groove 25 in the first part 21, the second groove 27 in the second part 23, and the support grooves 33 for the optical fibers 17 are drawn by broken lines. FIG. 9 is a perspective view showing a first part for the optical connecting device 11c shown in FIG. 3A. The second portion 21b of the first part 21 and the second portion 23b of the second part 23 are away from the first end face 13a (the first end face 21e) and the second end face 13b (the second end face 21f) of the holder 13. In the present embodiment, the first part 21 includes a first portion 21a, a second portion 21b, another first portion 21a, another second portion 21b, and a further first portion 21a, which are arranged in the direction of the first axis Ax1. The first portion 21a and the further first portion 21a include a first end face 21e and a second end face 21f, respectively. Each of the second portion 21b and the other second portion 21b includes a first opening 29a, a second opening 29b, and a third opening 29c. The second portion 21b and the other second portion 21b have substantially the same structure, and the first portion 21a, the other first portion 21a and the further first portion 21a have substantially the same structure. For simplicity, the following description is made for the other first and second portions 21a and 21b.

As shown in FIGS. 3A, 3B, 3C, 3D and 3E, the first opening 29a, the second opening 29b, and the third opening 29c are disposed in the second portion 21b. The first opening 29a extends from the first side face 13c of the holder 13 in the direction of the third axis Ax3, and the second opening 29b extends from the second side face 13d of the holder 13 in the direction of the third axis Ax3. The third opening 29c connects the first opening 29a and the second opening 29b to each other. The second side face 21d is opposite to the first side face 21c. In the present embodiment, the first opening 29a, the second opening 29b, and the third opening 29c are aligned in a line. The resin body 19 in the first and second grooves 25 and 27 continues to that in the first opening 29a, the second opening 29b and the third opening 29c, and the alignment of the first opening 29a, the second opening 29b and the third opening 29c makes it easy for the resin body 19 to deform in the direction of the alignment. Referring to FIG. 9, in the optical connecting device 11a, the first opening 29a has a groove 31 which extends from the first side face 21c of the first part 21 to reach the first groove 25, which is closer to the first side face 21c, and the second opening 29b has a groove 31 which extends from the second side face 21d of the first part 21 to reach the other first groove 25, which is closer to the second side face 21d. The third opening 29c also has a further groove 31 in the second portion 21b, and the further groove 31 connects the two first grooves 25 to each other. The three grooves 31 are aligned to form a single groove extending in a direction from one of the first side face 21c and the second side face 21d to the other. In the present embodiment, each groove 31 has a bottom face 31a, a first side face 31b and a second side face 31c. The grooves 31 of the first and second openings 29a and 29b are apart from the optical fibers 17 and the supporting grooves 33, and the further groove 31 of the third opening 29c crosses the supporting grooves 33.

The resin body 19 is in contact with the outer side face 15a of the guide member 15 in the second portions 21b and 23b of the first and second parts 21 and 23, and is provided in the first opening 29a, the second opening 29b, and the third opening 29 c. In the second portions 21b and 23b, the third opening 29c guides the resin body 19 therein both to the first opening 29a and one of the first grooves 25 and to the second opening 29b and the other first grooves 25 to integrate the resin body 19 in the first to third openings 29a, 29c and 29c, thereby forming a continuous resin. The resin body 19 not only is disposed in the first groove 25 and the first opening 29a but continuously extends to the second opening 29b via the third opening 29c. In the present embodiment, the grooves 31 are deeper than the first grooves 25, and the deep grooves 31 allows resin, which has not been cured yet, to flow out from the first grooves 25 to the first opening 29a, the second opening 29b, and the third opening 29c. The resin body 19 may not fill the deep groove 31, and then has a void in the grooves 31. The grooves 31 are fabricated with, for example, a precision grinding machine.

In fabricating the optical connecting device 11c, the optical fibers 17 (if needed, the guide member 15) are arranged on the members for the first part 21 and the second part 23, and liquid resin is provided on the arrangement of the optical fibers 17, and the liquid resin thus provided is cured to secure the optical fibers 17 to the members. In order to fill gaps between the outer face 15a of the guide member 15 and the faces (25a, 25b, 27a, 27b, and 27c) of the first and second grooves 25 and 27 with the resin body 19, liquid resin can be supplied from the first opening 29a and/or the second opening 29b by injection, and the space between the first part 21 and the second part 23 is provided with a desired amount of resin, and if any, a surplus of the resin thus injected can flow out into the first opening 29a, the second opening 29b and the third opening 29c through the first and second grooves 25 and 27. In fabricating the optical connecting device 11c, the third opening 29c makes it possible to form an integral resin independently of the difference between amounts of resin supplied from the first opening 29a and the second opening 29b.

In the first portion 21a and the further first portion 21a, preferably, the resin body 19 is not provided in the first groove 25 and the second groove 27. The second portion 21b and the other second portion 21b disable the supplied resin to flow into the first portion 21a, which is closer to the first end face 21e, and the still other first portion 21a, which is closer to the second end face 21f, respectively, and can prevent the supplied resin from overflowing therefrom to the end of the guide member 15. The second portion 21b and the other second portion 21b each may be apart from the first end face 21e and the second end face 21f, respectively, by a distance in the range of 100 to 2000 micrometers. The second portion 21b, the other second portion 21b, and the other first portion 21a, which is between the second portion 21b and the other second portion 21b, can provide the members with the primary adhesion.

In the optical connecting device 11c thus fabricated, temperature changes thereof cause the holder 13 and the guide member 15 to deform according to the respective thermal properties, and the deformation of the guide member 15 is transferred to the resin body 19, which is continuously disposed in the first opening 29a and the first opening 29b of the holder 13. The first opening 29a extends in the direction from the first groove 25 to the first side face 13c (the first side face 21c of the first part 21), specifically, in the direction of the third axis Ax3, and the second opening 29b extends in the direction from the first groove 25 to the second side face 13d (the second side face 21d of the first part 21). These directions are different from the direction in which the first and second parts 21 and 23 are arranged (the second axis Ax2). The resin body 19 can deform in the first, second and third openings 29a, 29b and 29c.

In the first portion 21a of the first part 21 and the first portion 23a of the second part 23, the resin body 19 provided between the first part 21 and the second part 23 is in direct contact with the outer face 15a of the guide member 15 in the first and second grooves 25 and 27. In the second portion 21b, the second portion 23b and the other second portion 23b, the resin body 19 between the first part 21 and the second part 23 can deform in the first and second openings 29a and 29b, without being restricted by the holder 13, in the direction in which the reference plane REF extends. This deformation is effective in lowering the stress of the resin body 19.

In the optical connecting device 11c, the first and second openings 29a and 29b extend in the direction of the third axis Ax3 to reach the first and second side faces 13c and 13d, respectively, and the resin body 19 continuously extending in the directions from the first grooves 25 to the first and second openings 29a and 29b makes it possible to reduce the internal stress of the resin body 19. The third opening 29c connects the two first grooves 25, so that the resin body 19 in the third opening 29c is effective in reducing imbalance in stress of the resin body 19 between the first opening 29a and the second opening 29b. Such an optical connecting device 11c can provide a desired heat resistance.

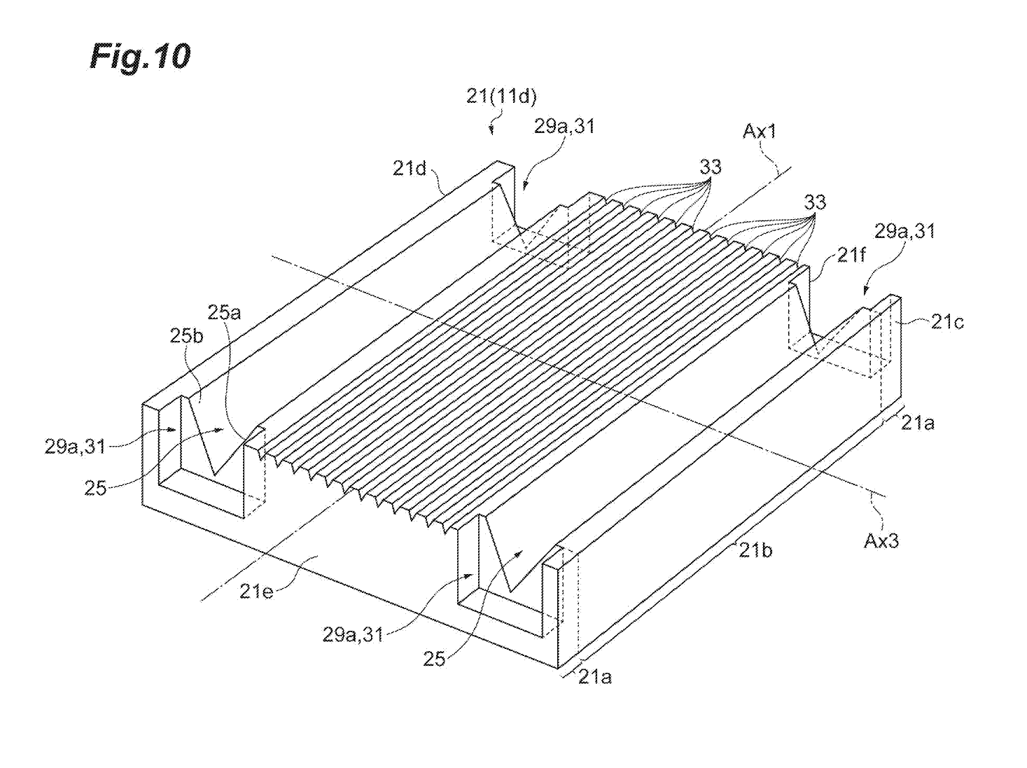

Referring to FIGS. 4A, 4B, 4C and 4D and FIG. 10, the optical connecting device 11d will be described below. In FIG. 4A, the support grooves 33 for the optical fibers 17, the first grooves 25 in the first part 21, and the second grooves 27 in the second part 23 are drawn by broken lines. FIG. 10 is a perspective view showing a first part for the optical connecting device 11d shown in FIG. 4A.

As shown in FIGS. 4A, 4B, 4C and 4D, the first end face 13a of the holder 13 has a first opening 29a at one end in each first groove 25, and the second end face 13b of the holder 13 has another first opening 29a at the other end of each first groove 25. These first openings 29a extend inward from the first and second end faces 13a and 13b in the direction of the first axis Ax1. The first end face 13a (21e) is opposite to the second end face 13b (21f). Referring to FIG. 10, in the optical connecting device 11d, the first openings 29a have respective grooves 31, which extend from the first and second end faces 21e and 21f of the first part 21 (and the second part 23), in the portion 21b thereof. These grooves 31 extend in a direction from one of the first and second end faces 21e and 21f to the other. In the present embodiment, each groove 31 has a bottom face 31a, a first side face 31b and a second side face 31c. The first opening 29a and the groove 31 are apart from the optical fibers 17 and the support groove 33. The first opening 29a and the groove 31 do not interfere with the arrangement of the optical fibers 17. The first opening 29a and the groove 31 each have a width small enough to be apart from the support grooves 33. The support grooves 33 are disposed in a thick portion of the first part 21, and extend from the first end face 21e to the second end face 21f.

In the present embodiment, the second portion 21b, the first portion 21a, and another second portion 21b are arranged in the direction of the first axis Ax1, and the second portion 21b and the other second portion 21b include a first end face 21e and a second end face 21f, respectively. The grooves 31 are outside the first portion 21a (23a) of the first part 21 (the second part 23), and are positioned on the first end face 21e and the second end face 21f. In the second portion 21b of the first part 21, the grooves 31 are deeper than the first groove 25, and the grooves in the second portion 23b of the second part 23 has a depth equal to or greater than that of the second groove 27. The grooves 31 on the first end face 21e of the first part 21 are aligned with the grooves 31 on the second end face 21f of the first part 21.

In fabricating the optical connecting device 11d, the optical fibers 17 (if needed, the guide member 15) are arranged between members for the first and second parts 21 and 23, and are fixed between these members with resin by curing. In order to fill gaps between the outer face 15a of the guide member 15 and the faces (25a, 25b, 27a, 27b, and 27c) of the first and second grooves 25 and 27 with the resin body 19, a desired amount of liquid resin is supplied thereto, so that a part of the resin is left between the first part 21 and the second part 23, and excess resin flows from the first and second grooves 25 and 27 into the first opening 29a. The first portion 21a, which is between the second portion 21b and the further second portion 21b, can provide the members with the main adhesion.

Each of the first and second end faces 13a 13b is disposed in the second portions 21b and 23b of the first and second parts 21 and 23. The guide member 15 protrudes from the first and second grooves 25 and 27 into the first opening 29a. This protrusion can prevent resin for the resin body 19 from contaminating the end or inner side of the guide member 15.

In the optical connecting device 11d thus fabricated, the holder 13 and the guide member 15 deform in response to temperature changes of the optical connecting device 11d. The deformation of the guide member 15 is transmitted to the resin body 19. The resin body 19 continues from the first and second grooves 25 and 27 to the first openings 29a, which are recessed from the first end face 13a, and the first openings 29a extend in directions from the first groove 25 to the first end face 13a (the first end face 21e) and the second end face 13b (the second end face 21f) (for example, the direction of the first axis Ax1). These directions are different from the direction (the direction of the second axis Ax2) in which the first and second parts 21 and 23 bonded are arranged. The first openings 29a allow the resin body 19 to deform therein.

The resin body 19 provided between the first part 21 and the second part 23 is brought into contact with the outer face 15a of the guide member 15, which is in each of the first and second grooves 25 and 27, in the first portions 21a and 23a of the first and second parts 21 and 23, and can deform in the second portion 21b and the second portion 23b free from restriction imposed by the holder 13 in the direction in which the plane REF extends. This deformation is effective in reducing the internal stress of the resin body 19.

In the optical connecting device 11d, the first opening 29a extends in the direction of the first axis Ax1 to the first end face 13a (the second end face 13b), and allows the resin body 19, continuing from the first groove 25 to the first opening 29a, to reduce the internal stress. The optical connecting device 11d can provide a desired heat resistance.

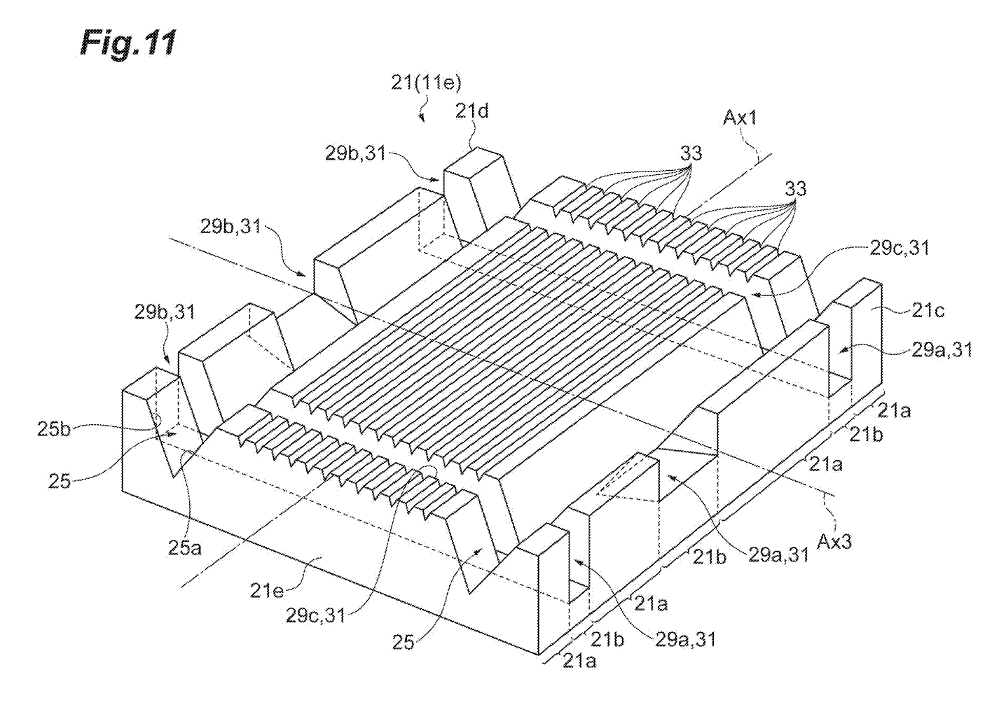

With reference to FIGS. 5A, 5B, 5C, 5D and 5E and FIG. 11, the optical connecting device 11e will be described below. In FIG. 5A, the first groove 25 in the first part 21, the second groove 27 in the second part 23, and the support grooves 33 for optical fibers are drawn by broken lines. FIG. 11 is a perspective view showing a first part for the optical connecting device 11e shown in FIG. 5A.

The first portion 21a, the second portion 21b, the other first portion 21a, the other second portion 21b, the further first portion 21a, the further second portion 21b, and the still other first portion 21a are arranged in the direction of the first axis Ax1. In the present embodiment, the optical connecting device 11e has a structure formed by combining the first opening 29a that the optical connecting device 11a shown in FIGS. 1A, 1B, 1C and 1D and FIG. 7 contains, and the first, the second and the third openings 29a, 29b, and 29c that the optical connecting device 11c shown in FIGS. 3A, 3B, 3C, 3D and 3E and FIG. 9 contains. In the optical connecting device 11e, specifically, the first portion 21a and the still other first portion 21a include a first end face 21e and a second end face 21f, respectively. The second portion 21b, the further second part 21b and the further second portion 21b each include the first opening 29a and the second opening 29b, and the second portion 21b and the further second portion 21b each include the third opening 29c.

In fabricating the optical connecting device 11e, the optical fibers 17 (if needed, the guide member 15) are arranged between members for the first and second parts 21 and 23, and these members are fixed therebetween with resin by curing. In order to fill gaps between the outer face 15a of the guide member 15 and the faces (25a, 25b, 27a, 27b, and 27c) of the first and second grooves 25 and 27 with the resin body 19, liquid resin is supplied thereto from the first opening 29a in the other second portion 21b, so that a desired amount of the liquid resin is left in the first and second grooves 25 and 27, and surplus resin flows from the first and second grooves 25 and 27 into the first opening 29a, the second opening 29b, and the third opening 29c, which are located in each of the second portion 21b and the further second portion 21b. In fabricating the optical connecting device 11e, the third opening 29c receives resin from the two first grooves 25 independent of the difference in the amounts of supplied resin between the first opening 29a and the second opening 29b.

Preferably, the resin body 19 is not provided in the first and second grooves 25 and 27 that the first portion 21a and the still other first portion 21a each include. The second portion 21b and the other second portion 21b disable the supplied resin to flow into the first portion 21a, which is closer to the first end face 21e, and the still other first portion 21a, which is closer to the second end face 21f, and can present the supplied resin from overflowing therefrom to the end of the guide member 15. The first portion 21a, which is between the second portion 21b and the other second portion 21b, and the other first portion 21a, which is between the further second portion 21b and the further second portion 21b, can provide the members with the main adhesion.

The optical connecting device 11e thus fabricated can reduce stress in the resin body 19 because of the action of the first opening 29a that the optical connecting device 11a contains shown in FIGS. 1A, 1B, 1C and 1D and FIG. 7 and the action of the first opening 29a, the second opening 29b and the third opening 29c that the optical connecting device 11c contains shown in FIGS. 3A, 3B, 3C, 3D and 3E and FIG. 9. The combination of the above openings can provide the optical connecting device 11e with a desired heat tolerance.

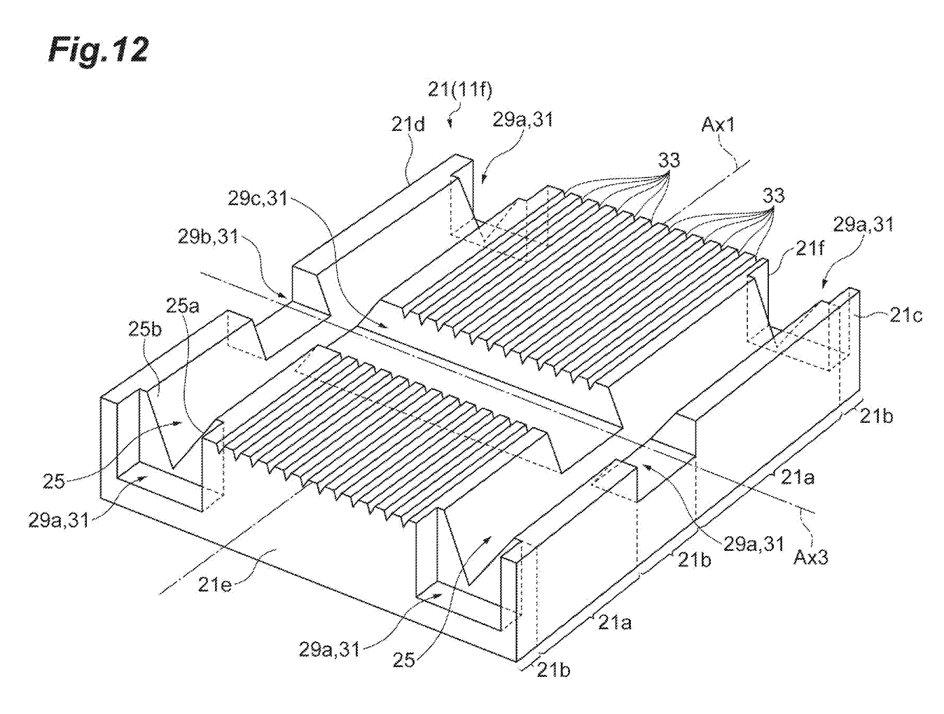

With reference to FIGS. 6A, 6B, 6C, 6D, 6E and 6F and FIG. 12, the optical connecting device 11f will be described below. In FIG. 6A, the first groove 25 in the first part 21, the second groove 27 in the second part 23, and the support grooves 33 for optical fibers are drawn by broken lines. FIG. 12 is a perspective view showing a first part for the optical connecting device 11f shown in FIG. 6A.

The second portion 21b, the first portion 21a, another second portion 21b, another first portion 21a, and a further second portion 21b are arranged in the direction of the first axis Ax1. In the present embodiment, the optical connecting device 11f has the first opening 29a, the second opening 29b and the third opening 29c that the optical connecting device 11b contains shown in FIGS. 2A, 2B, 2C and 2D and FIG. 8, and the first opening 29a that the optical connecting device 11d contains shown in FIGS. 4A, 4B, 4C and 4D. Specifically, in the optical connecting device 11f, the second portion 21b and the further second portion 21b include a first end face 21e and a second end face 21f, respectively. The other second portion 21b includes the first opening 29a, the second opening 29b, and the third opening 29c.

In fabricating the optical connecting device 11f, the optical fibers 17 (if needed, the guide member 15) are arranged between members for the first and second parts 21 and 23, and these members are fixed therebetween with resin by curing. In order to fill gaps between the outer face 15a of the guide member 15 and the faces (25a, 25b, 27a, 27b, and 27c) of the first and second grooves 25 and 27 with the resin body 19, the first opening 29a and the second opening 29b are used to supply liquid resin to the first and second grooves 25 and 27. The third opening 29c can average an unevenness of resin supplied through the first and second openings 29a and 29b. The first portion 21a, which is between the second portion 21b and the other second portion 21b, and the other first portion 21a, which is between the other second portion 21b and the further second portion 21b, provide the members with a main adhesion. Surplus resin flows out from the ends of the first grooves 25 and the second grooves 27 to the first openings 29a located on the end faces, and remains in the first openings 29a.

The first and second end faces 13a and 13b are provided in the second portion 21b of the first part 21 and the second portion 23b of the second part 23. The guide member 15 protrudes from the first and second grooves 25 and 27 into the first opening 29a. This protrusion can prevent the resin body 19 from covering the end of the guide member 15.

The optical connecting device 11f thus fabricated can reduce stress in the resin body 19 because of the action of the first, the second and the third openings 29a, 29b and 29c, which the optical connecting device 11b shown in FIGS. 2A, 2B, 2C and 2D and FIG. 8 includes, and the first opening 29a, which the optical connecting device 11d shown in FIGS. 4A, 4B, 4C and 4D and FIG. 10 includes. The combination of the above openings can provide the optical connecting device 11f with a desired heat tolerance.

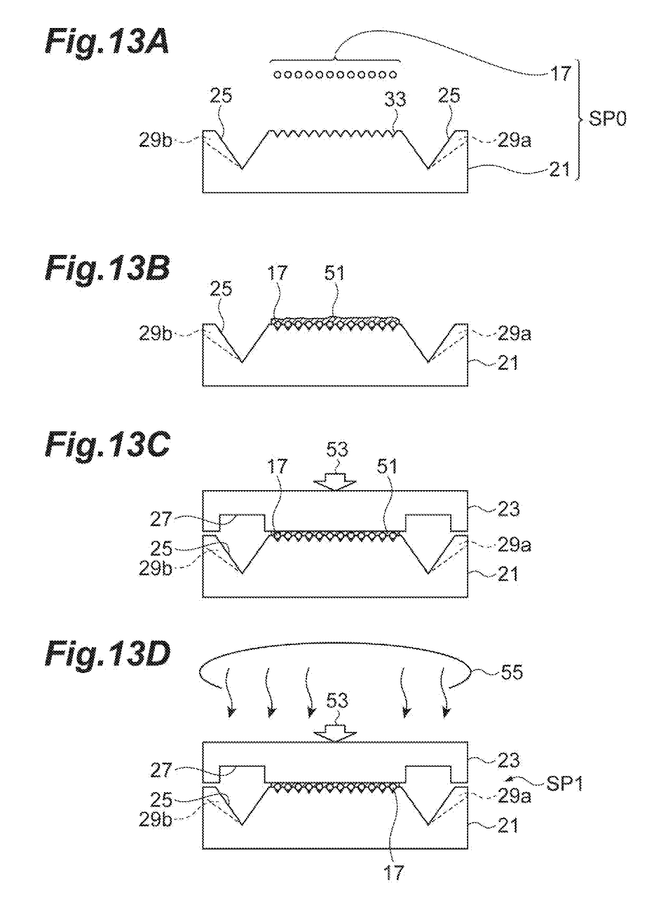

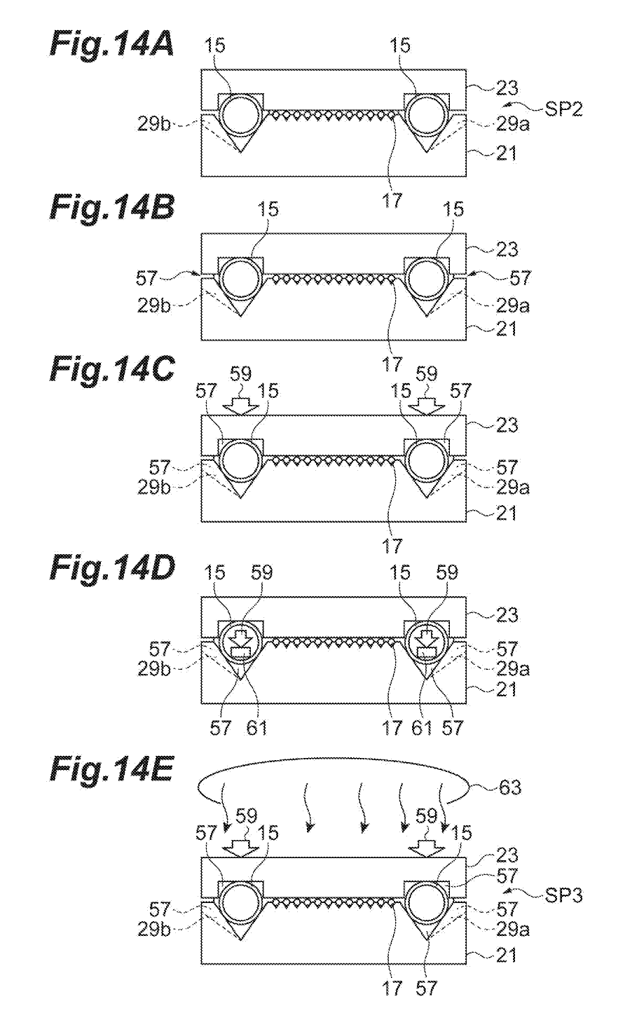

FIGS. 13A, 13B, 13C and 13D and FIGS. 14A, 14B, 14C, 14D and 14E are schematic views each showing a major step in the method of fabricating an optical connecting device according to the embodiment. As shown in FIG. 13A, the method includes a step of preparing parts for the first part 21 (for simplicity, hereinafter referred to as “a first part 21”) and optical fibers (for simplicity, hereinafter referred to as “optical fibers 17”). The first part 21 has grooves for the guide member (for simplicity, hereinafter referred to as “first grooves 25”) and grooves for the optical fibers (for simplicity, “supporting grooves 33”). The optical fibers 17 and the first part 21 thus combined are referred to as a part SP0.

As shown in FIG. 13B, the optical fibers 17 are arranged on the support grooves 33 of the first part 21. The resin 51 is applied to the supporting grooves 33 of the first part 21 and the optical fibers 17 outside the first grooves 25 of the first part 21. The resin 51 contains, for example, at least one of a thermosetting agent or an ultraviolet curing agent.

As shown in FIG. 13C, the method includes a step for preparing a part for the second part 23. The part for the second part 23 (for the sake of simplicity, hereinafter referred to as the “a second part 23”) has grooves for the guide member (hereinafter referred to as the “second grooves 27”). The second part 23 is placed to cover the optical fibers 17, the applied resin, and the supporting grooves 33, which have already placed on the first part 21. The optical fibers 17 are positioned on the second part 23 by applying a pressing force 53 to the first part 21.

As shown in FIG. 13D, the positioning is followed by a hardening treatment 55 of curing the resin 51 with the first part 21 and the second part 23 being pressed, thereby obtaining a first product SP1. The curing can include, for example, thermosetting or ultraviolet curing. The temperature of a heat treatment for thermal curing is, for example, in the range of 80 to 200 degrees Celsius.

As shown in FIG. 14A, the method includes a step for preparing a part for the guide member 15 (for simplicity, hereinafter referred to as “a guide member 15”). In the present embodiment, the guide member 15 is disposed in the first and second grooves 25 and 27 of the first product SP1. Preferably, in order to allow the insertion of the guide member 15 into the first product SP1 including the optical fibers 17 fixed with the resin 51, resin for the resin 51 is supplied by an amount that prevents the resin thus supplied from overflowing to the first and second grooves 25 and 27 in placing the second part 23 on the first part 21.

If needed, the guide member 15 can be placed in the first groove 25 of the first part 21 before the second part 23 is placed on the support grooves 33 of the first part 21, the optical fibers 17 and the resin. An assembly including the first product SP1 and the guide member 15 is referred to as a second product SP2.

As shown in FIG. 14B, in fixing the guide member 15 in the second product SP2, an additional resin 57 may be injected from the first opening 29a and/or the second opening 29b.

As shown in FIG. 14C, the guide member 15 is positioned by applying a pressing force 59 to the first part 21 and the second part 23 in alignment to the guide member 15. Alternatively, as shown in FIG. 14D, the guide member 15, specifically, a guide pipe prepared as the guide member 15, is positioned by applying a pressing force 59 to the guide pipe with a jig 16, which is inserted into a hole of the guide pipe in the present embodiment.

As shown in FIG. 14E, after the positioning, the resin 57 is cured by a treatment 63 for curing with the first part 21 and the second part 23 being pressed, thereby forming a third product SP3.

The above steps bring a stub type optical connecting device 11 to completion.

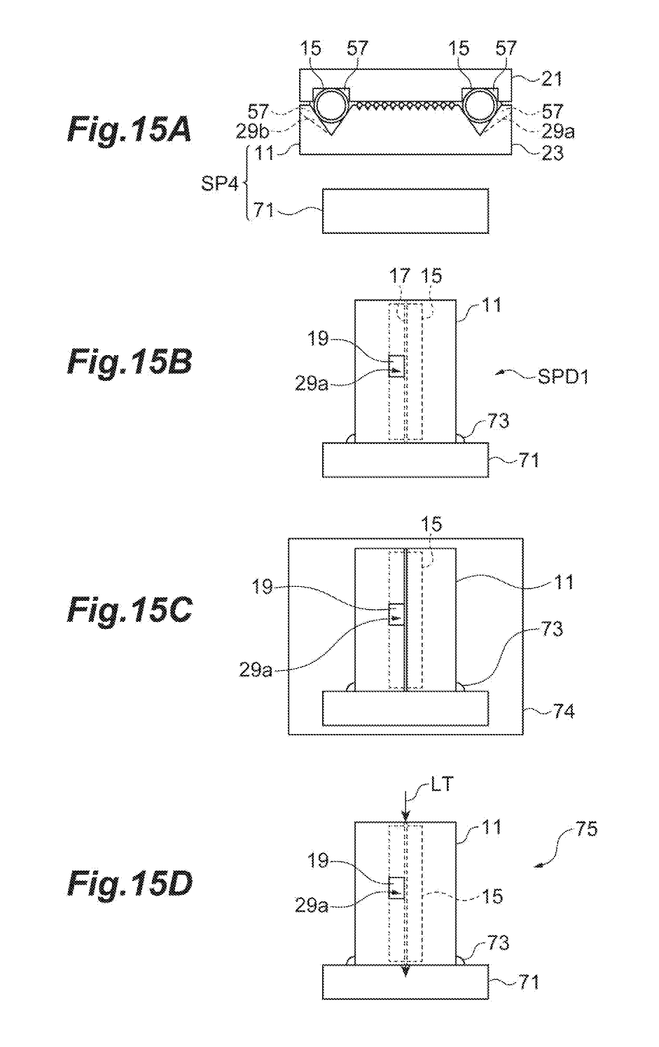

FIGS. 15A, 15B, 15C, and 15D are schematic views showing major steps in a method of fabricating an optical processing apparatus. As shown in FIG. 15A, the optical connecting device 11 is prepared, and the optical connecting device 11 can be fabricated by, for example, the method already described above. Further, a semiconductor device 71 is prepared, and the semiconductor device 71 has an optical coupling element(s) therein. The semiconductor device 71 may include a semiconductor optical device, such as a silicon photonics device. The optical connecting device 11 and the semiconductor device 71 are referred to as a part SP4.

As shown in FIG. 15B, the optical connecting device 11 is mounted on the semiconductor element 71 so as to be optically coupled to the optical coupling element of the semiconductor device 71. After the optical alignment is performed, the optical connecting device 11 is fixed to the semiconductor device 71 with the resin 73 by curing. This curing can be, for example, thermal curing or ultraviolet curing. The temperature of heat treatment in the thermal curing is, for example, in the range of 80 to 200 degrees Celsius, for example 120 degrees. The above steps bring a product SPD1 to completion. The product SPD1 includes the semiconductor device 71 and the optical connecting device 11, and the optical connecting device 11 is optically coupled to the semiconductor device 71.

As shown in FIG. 15C, for example, a heat treatment for soldering reflow is performed on the product SPD1. The temperature of the heat treatment is, for example, in the range of 150 to 300 degrees Celsius, for example 300 degrees Celsius. Reflow is a method in which solder paste printed on a printed circuit board or ball-shaped solder formed on a part is heated in a furnace to a solder-melting temperature to melt solder. The product SPD1 is loaded to a reflow device 74. All the process steps to the reflow bring the optical processing device 75 shown in FIG. 15D to completion. The optical processing device 75 can receive the optical signal LT from the optical connecting device 11 and can provide the optical signal LT to the optical connecting device 11. The temperature of the optical connecting device 11 during the operation of the optical processing device 75 is in the range of, for example, 40 to 100 degrees Celsius, for example, 100 degrees Celsius, due to the heat generated by the semiconductor device 71.

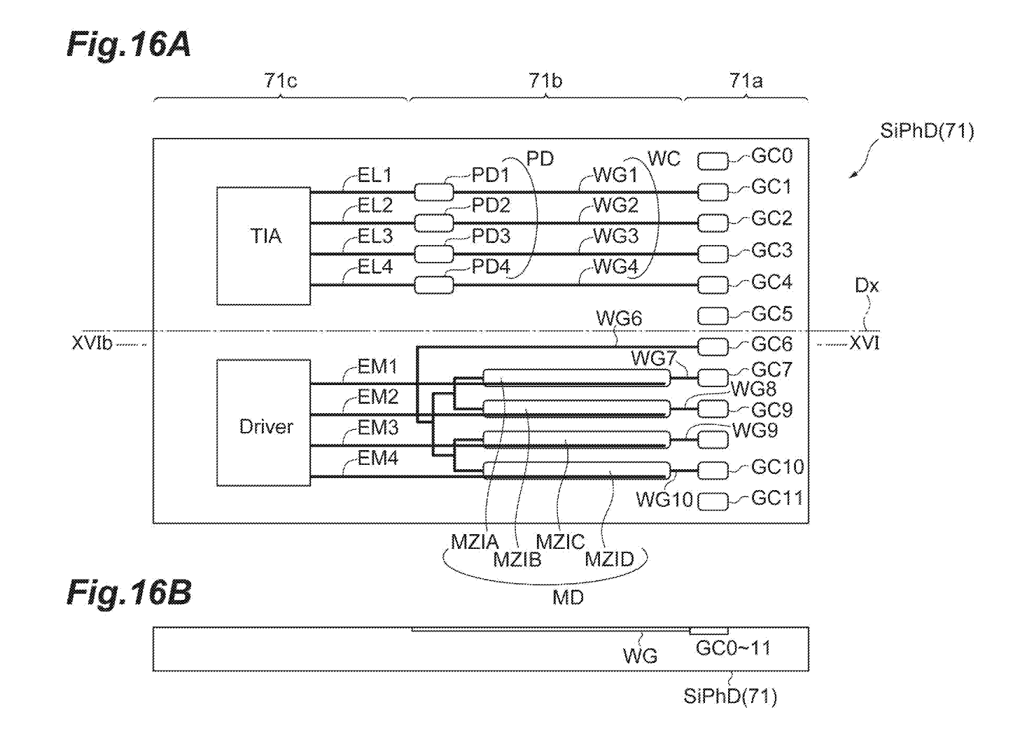

FIGS. 16A and 16B are views showing an example of a silicon photonics semiconductor device applicable to the optical device according to the present embodiment. FIG. 16A shows a plan view of the silicon photonic semiconductor device. FIG. 16B is a cross-sectional view, taken along line XVIb-XVIb shown in FIG. 16A, showing the silicon photonic semiconductor device. As shown in FIG. 16A, the silicon photonics semiconductor device SiPhD includes an optical coupling element, such as grating couplers GC0, GC1, GC2, GC3, GC4, GC5, GC6, GC7, GC8, CG9, CG10, GC11 (12 grating couplers), integrated therein.

In the present embodiment, the grating couplers GC1 to CG4 are prepared for the optical receiver. Signal light beams from the grating couplers GC1 to CG4 are provided to the light receiving elements PD through the optical circuit WC. In the present embodiment, the optical circuit WC includes optical waveguides WG1 to WG4. The grating couplers GC1 to CG4 are optically coupled to photodiodes PD1 to PD4 via the optical waveguides WG1 to WG4, respectively. The photodiodes PD1 to PD4, which are integrated in the silicon photonic semiconductor device, are connected to an electric circuit TIA (for example, a transimpedance amplifier), which are integrated in the silicon photonic semiconductor device, via conductive lines EL1 to EL4. The electric circuit TIA performs processing (for example, current-voltage conversion, amplification) of electric signals (for example, photocurrent) from the photodiodes PD1 to PD4 to generate electric signals in response to the received signal light beams.

In addition, the grating couplers GC6 to CG10 are prepared for the optical transmitter. In the present embodiment, the laser light beam from the grating coupler GC6 is supplied to an optical modulator MD. The optical modulator MD includes, for example, a Mach-Zehnder modulator MZIA, MZIB, MZIC, and MZID. The Mach-Zehnder modulators MZIA to MZID receive the electric signals EM 1 to EM 4 from a drive circuit, Driver, which are integrated in the silicon photonic semiconductor device, respectively, and generate modulated light beams in response to the electric signals EM1 to EM4. These modulated light beams propagate through the optical waveguides WG7 to WG10 to the grating couplers GC7 to CG10, respectively.

The silicon photonics semiconductor element SiPhD includes a first portion 71a, a second portion 71b, and a third portion 71c, which are arranged in a line. The first portion 71a includes an arrangement of grating couplers GC0 to CG11, which are arranged along one edge that the first portion 71a includes. The second portion 71b includes optical elements, such as semiconductor light receiving elements and/or optical modulators. The third portion 71c includes electric circuits, such as the electric circuit TIA and the drive circuit, Driver.

Referring to FIG. 16B, in the silicon photonic semiconductor device SiPhD, the grating couplers GC0 to CG11 are coupled to the optical waveguides WG.

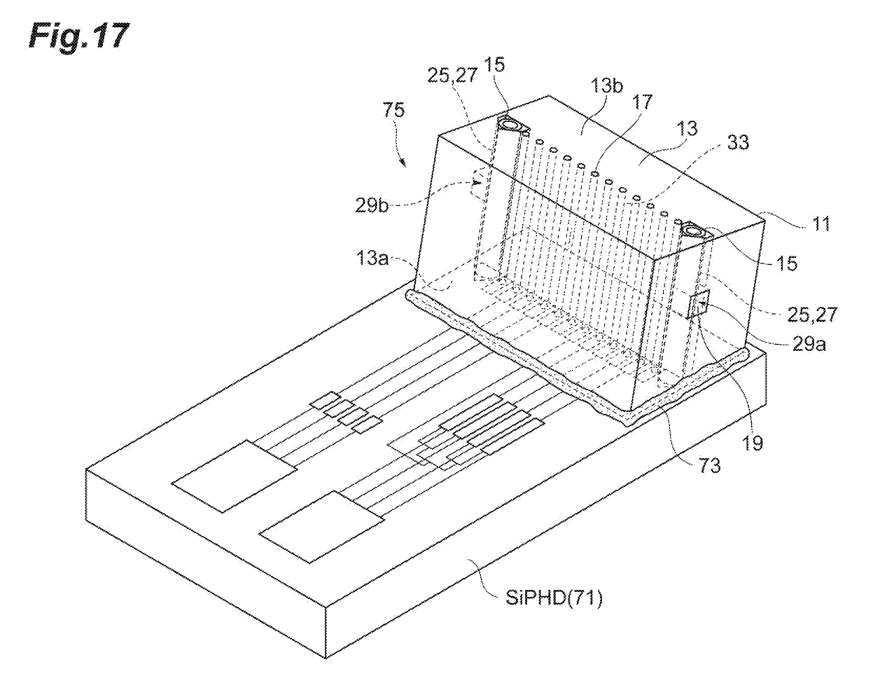

FIG. 17 is a schematic view showing the optical processing apparatus according to the present embodiment. The optical processing device 77 includes an optical connecting device 11, such as a fiber stub according to the present embodiment, an optical integrated device, such as a silicon photonic device SiPHD, and a resin body (a cured resin 73). The above adhesive is used to fix the fiber stub to the optical integrated device. The optical processing device 77 is fabricated by the above process in which the heat treatment in the reflow process is applied to an assembly including the fiber stub mounted on the optical integrated device such that the optical fibers of the fiber stub can be optically coupled to the optical integrated device, and the fabrication process causes less damage to optical processing device 77. The silicon photonic device SiPHD above with reference to FIGS. 16A and 16B is shown as an example of an optical integrated device.

Sizes of an exemplary fiber stub according to the present embodiment.
Length: in the range of 1 to 5 mm, for example 3 mm.
Width: in the range of 2 to 10 mm, for example 6 mm.
Height: in the range of 2 to 10 mm, for example 5 mm.

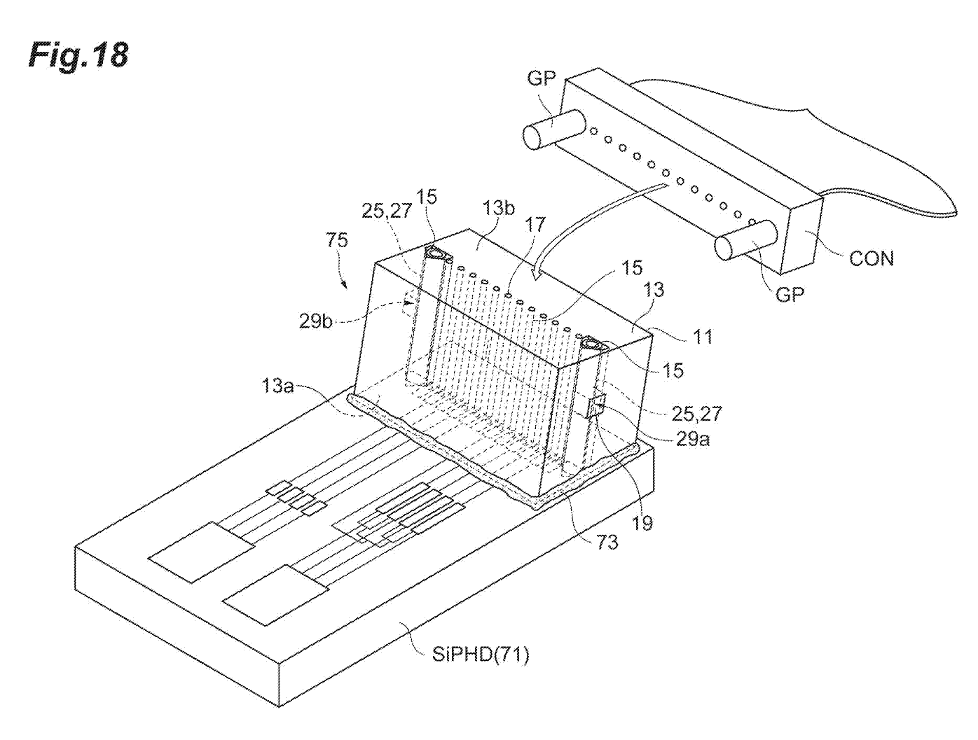

FIG. 18 is a schematic view showing the optical processing apparatus according to the present embodiment. In the optical processing device 77, the optical connecting device 11 is fixed to the silicon photonics semiconductor device SiPhD. As shown in FIG. 18, a pigtail type optical connector CON is connected to the optical connecting device 11 of the optical processing device 77. In order to optically couple the fiber stub of the optical processing device 77 to the optical connector CON, the guide pin PG of the optical connector CON is inserted into one end of the guide pipe of the fiber stub to align the optical connector CON with respect to the fiber stub. This optical coupling allows the silicon photonic semiconductor device SiPhD to optically communicate with another device via the fiber stub and the optical connector CON. Removing the optical connector CON with a long pigtail from the assembly product can make it easy to handle the assembly product. The optical connector CON may have a lower heat resistance than that required for assembling processes.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. An optical connecting device including:
a holder including a first end face, a second end face, a first part, and a second part, the first end face and the second end face being arranged in a direction of a first axis, and the first part and the second part being arranged in a direction of a second axis intersecting the direction of the first axis;
a guiding member supported by the first part and the second part and having a side face, the side face extending in the direction of the first axis between the first part and the second part;
a plurality of optical fibers arranged along a reference plane between the first part and the second part in a direction of a third axis intersecting the direction of the second axis and the direction of the first axis; and
a resin body disposed between the first part and the second part,
the plurality of optical fibers extending from the first end face in the direction of the first axis,
the holder having a first side face extending in the direction of the first axis,
each of the first part and the second part having a first portion and a second portion, and the first portion and the second portion being arranged in the direction of the first axis,
the first portion in one of the first part and the second part having a first groove extending in the direction of the second axis, the first groove having a first supporting face and a second supporting face, and the first supporting face and the second supporting face supporting the guiding member,
the first portion in another of the first part and the second part having a third supporting face, the third supporting face supporting the guiding member,
the second portion of the first part having a first opening extending from one of the first side face and the first end face to the first groove,
in the first portions of the first part and the second part, the resin body being disposed between the side face of the guiding member and the first supporting face and the second supporting face of the first groove and between the side face of the guiding member and the third supporting face of the second part, and
in the second portions of the first part and the second part, the resin body being disposed in the first opening.

2. The optical connecting device according to claim 1, wherein the first end face is in the first portions of the first part and the second part,
the resin body is in contact with the side face of the guiding member in the second portions of the first part and the second part, and
the first opening extends from the first side face of the holder in the direction of the third axis.

3. The optical connecting device according to claim 1, wherein the second portion of the first part has a groove extending from the first side face to the first groove, and the groove has a depth shallower than that of the first groove.

4. The optical connecting device according to claim 1, wherein the second portion of the first part has a groove extending from the first side face to the first groove, and the groove has a depth larger than that of the first groove.

5. The optical connecting device according to claim 1, wherein the second portions of the first part and the second part are apart from the end face and the second end face,
the holder has a second side face opposite to the first side face,
the second portion of the first part has a second opening and a third opening, the second opening is disposed in the second side face, and the third opening connects the second opening to the first groove,
the second opening extends in a direction of the second side face to the first side face,
the resin body is in contact with the side face of the guiding member in the second portions of the first part and the second part, and is disposed in the first opening, and
the resin body extends from the first groove in the second opening and the third opening in the second portions of the first part and the second part.

6. The optical connecting device according to claim 5, wherein the first opening, the second opening and the third opening are aligned in a line.

7. The optical connecting device according to claim 1, wherein the second portions of the first part and the second part are apart from the first end face and the second end face, and the first opening is apart from the plurality of optical fibers.

8. The optical connecting device according to claim 1, wherein the first end face is in the first portions of the first part and the second part,
the first opening is in the first end face, and
the guiding member protrudes from the first groove and extends in the first opening.

9. The optical connecting device according to claim 1, wherein the guiding member includes a guide pin made of metal.

10. The optical connecting device according to claim 1, wherein the guiding member includes a guide pipe made of metal.

11. An optical processing apparatus including:
an optical connecting device; and
a semiconductor device mounting the optical connecting device so as to be optically coupled thereto,
the semiconductor device including an optical coupling element optically coupled to the optical connecting device,
the optical connecting device including:
a holder including a first end face, a second end face, a first part, and a second part, the first end face and the second end face being arranged in a direction of a first axis, and the first part and the second part being arranged in a direction of a second axis intersecting the direction of the first axis;
a guiding member supported by the first part and the second part and having a side face, the side face extending in the direction of the first axis between the first part and the second part;
a plurality of optical fibers arranged along a reference plane between the first part and the second part in a direction of a third axis intersecting the direction of the second axis and the direction of the first axis; and
a resin body disposed between the first part and the second part,
the plurality of optical fibers extending from the first end face in the direction of the first axis,
the holder having a first side face extending in the direction of the first axis,
each of the first part and the second part having a first portion and a second portion, and the first portion and the second portion being arranged in the direction of the first axis,
the first portion in one of the first part and the second part having a first groove extending in the direction of the second axis, the first groove having a first supporting face and a second supporting face, and the first supporting face and the second supporting face supporting the guiding member,
the first portion in another of the first part and the second part having a third supporting face, the third supporting face supporting the guiding member,
the second portion of the first part having a first opening extending from one of the first side face and the first end face to the first groove,
in the first portions of the first part and the second part, the resin body being disposed between the side face of the guiding member and the first supporting face and the second supporting face of the first groove and between the side face of the guiding member and the third supporting face of the second part, and
in the second portions of the first part and the second part, the resin body being disposed in the first opening.

12. A method for fabricating an optical processing apparatus including steps of:
preparing an optical connecting device;
preparing a semiconductor device including an optical coupling element;
mounting the optical connecting device on the semiconductor device to form a product such that the optical connecting device is optically coupled to the semiconductor device; and
subjecting the product to heat treatment for reflowing,
the optical connecting device including:
a holder including a first end face, a second end face, a first part, and a second part, the first end face and the second end face being arranged in a direction of a first axis, and the first part and the second part being arranged in a direction of a second axis intersecting the direction of the first axis;
a guiding member supported by the first part and the second part and having a side face, the side face extending in the direction of the first axis between the first part and the second part;
a plurality of optical fibers arranged along a reference plane between the first part and the second part in a direction of a third axis intersecting the direction of the second axis and the direction of the first axis; and
a resin body disposed between the first part and the second part,
the plurality of optical fibers extending from the first end face in the direction of the first axis,
the holder having a first side face extending in the direction of the first axis,
each of the first part and the second part having a first portion and a second portion, and the first portion and the second portion being arranged in the direction of the first axis,
the first portion in one of the first part and the second part having a first groove extending in the direction of the second axis, the first groove having a first supporting face and a second supporting face, and the first supporting face and the second supporting face supporting the guiding member,
the first portion in another of the first part and the second part having a third supporting face, the third supporting face supporting the guiding member,
the second portion of the first part having a first opening extending from one of the first side face and the first end face to the first groove,
in the first portions of the first part and the second part, the resin body being disposed between the side face of the guiding member and the first supporting face and the second supporting face of the first groove and between the side face of the guiding member and the third supporting face of the second part, and
in the second portions of the first part and the second part, the resin body being disposed in the first opening.
